(19) United States
(12) Patent Application Publication
(10) Pub. No.: US 2024/0047579 A1
(43) Pub. Date: Feb. 8, 2024

(54) SEMICONDUCTOR DEVICE

(71) Applicant: SAMSUNG ELECTRONICS CO., LTD., Suwon-si (KR)

(72) Inventor: Seonhaeng LEE, Suwon-si (KR)

(21) Appl. No.: 18/199,504

(22) Filed: May 19, 2023

(30) Foreign Application Priority Data
Aug. 8, 2022 (KR) 10-2022-0098839

(51) Int. Cl. H01L 29/78; H01L 21/768; H01L 21/22; H01L 21/762; H10B 12/00; H10B 41/00; H10B 43/00

(52) U.S. Cl. CPC H01L 29/7833; H01L 21/76898; H01L 21/22; H01L 21/762; H01L 21/76832; H10B 12/30; H10B 41/00; H10B 43/00

(57) ABSTRACT

A semiconductor device includes a substrate including first and second surfaces opposing each other. A device isolation layer extends through the substrate and defines an active region in the substrate. A gate electrode is on the first surface of the substrate. A wiring structure electrically connects the gate electrode and the active region. The active region includes a target doped region between the device isolation layer and the gate electrode and including a dopant having a first concentration. A path doped region is between the device isolation layer and the gate electrode and extends from the second surface of the substrate to the target doped region. The path doped region includes a dopant having a second concentration less than the first concentration. The target doped region and the path doped region are formed by implanting the dopant through the second surface of the substrate.

### CROSS-REFERENCE TO RELATED APPLICATION

This application claims priority under 35 U.S.C. § 119 to Korean Patent Application No. 10-2022-0098839, filed on Aug. 8, 2022 in the Korean Intellectual Property Office, the disclosure of which is incorporated by reference in its entirety herein.

### TECHNICAL FIELD

The present inventive concept relates to a semiconductor device, and more particularly, to a semiconductor device including a transistor.

### DISCUSSION OF RELATED ART

A high degree of integration of semiconductor devices is desired to provide excellent performance and economic feasibility. In particular, the degree of integration of memory devices is a main factor determining the economic feasibility of products.

However, recently, due to a high-temperature process of semiconductor devices, scaling down of transistors in memory devices has reached a limit. Applying a low-temperature process to semiconductor devices makes it difficult to obtain desired characteristics of memory devices, and thus, it may be difficult to apply the low-temperature process to semiconductor devices.

### SUMMARY

Embodiments of the present inventive concept provide a semiconductor device having transistors having increased reliability and performance by preventing a change in performance of the transistors that may occur during a high-temperature process.

The problems to be solved by embodiments of the present inventive concept are not limited to the problems mentioned above, and other problems not mentioned may be clearly understood by those skilled in the art from the following description.

According to an embodiment of the present inventive concept, a semiconductor device includes a substrate including first and second surfaces opposing each other. A device isolation layer extends through the substrate. The device isolation layer defines an active region in the substrate. A gate electrode is on the first surface of the substrate. A wiring structure is on the first surface of the substrate. The wiring structure is electrically connected to the gate electrode and the active region. A protective layer covers the wiring structure. The protective layer includes an insulating material. A first surface of the device isolation layer is coplanar with the first surface of the substrate. A second surface of the device isolation layer is coplanar with the second surface of the substrate. The active region includes a target doped region between the device isolation layer and the gate electrode. The target doped region includes a dopant having a first concentration. A path doped region is between the device isolation layer and the gate electrode and extends from the second surface of the substrate to the target doped region. The path doped region includes a dopant having a second concentration less than the first concentration. The target doped region abuts the first surface of the substrate. The path doped region abuts the second surface of the substrate. The target doped region and the path doped region are formed by implanting the dopant through the second surface of the substrate. The substrate is thinned by grinding the second surface of the substrate to expose the second surface of the device isolation layer.

According to an embodiment of the present inventive concept, a semiconductor device includes a substrate including first and second surfaces opposite to each other. A device isolation layer extends through the substrate in a vertical direction. The device isolation layer defines an active region in the substrate. A gate electrode structure is disposed within the substrate. The gate electrode structure extends in a first horizontal direction. A wiring structure is on the substrate. A protective layer covers the wiring structure. The protective layer includes an insulating material. The wiring structure includes a bit line. The bit line extends in a second horizontal direction orthogonal to the first horizontal direction. A first surface of the device isolation layer is coplanar with the first surface of the substrate. A second surface of the device isolation layer is coplanar with the second surface of the substrate. The active region includes a target doped region between the device isolation layer and the gate electrode structure. The target doped region includes a dopant having a first concentration. A path doped region is between the device isolation layer and the gate electrode structure. The path doped region extends from the second surface of the substrate to the target doped region. The path doped region includes a dopant having a second concentration less than the first concentration. The target doped region abuts the first surface of the substrate. The path doped region abuts the second surface of the substrate. The target doped region and the path doped region are formed by implanting the dopant through the second surface of the substrate. The substrate is thinned by grinding the second surface of the substrate to expose the second surface of the device isolation layer.

According to an embodiment of the present inventive concept, a semiconductor device includes a peripheral structure. A cell structure is on the peripheral structure. A protective layer covers the cell structure. The protective layer includes an insulating material. The peripheral structure includes a substrate including first and second surfaces opposing each other. A device isolation layer extends through the substrate. The device isolation layer defines an active region in the substrate. A gate electrode is on the first surface of the substrate. A wiring structure is on the first surface of the substrate. The wiring structure is electrically connected to the gate electrode. The cell structure includes a stack structure disposed on the wiring structure and including a plurality of conductive layers and a plurality of interlayer insulating layers that are alternately stacked. A channel structure extends through the stack structure. A first surface of the device isolation layer is coplanar with the first surface of the substrate. A second surface of the device isolation layer is coplanar with the second surface of the substrate. The active region includes a target doped region between the device isolation layer and the gate electrode. The target doped region includes a dopant having a first concentration. A path doped region is between the device isolation layer and the gate electrode and extends from the second surface of the substrate to the target doped region. The path doped region includes a dopant having a second concentration less than the first concentration. The target doped region abuts the first surface of the substrate. The path doped region abuts the second surface of the substrate. The target doped region and the path doped region are formed by implanting the dopant through the second surface of the substrate. The substrate is thinned by grinding the second surface of the substrate to expose the second surface of the device isolation layer.

### BRIEF DESCRIPTION OF THE DRAWINGS

Embodiments will be more clearly understood from the following detailed description taken in conjunction with the accompanying drawings in which:

FIG. 1 is a cross-sectional view illustrating a semiconductor device according to an embodiment of the present inventive concept;

FIG. 2 is an enlarged cross-sectional view illustrating only a partial configuration of the semiconductor device shown in FIG. 1 according to an embodiment of the present inventive concept;

FIGS. 3A and 3B are cross-sectional views, in which FIG. 3A illustrates a comparative example of an embodiment illustrated in FIG. 3B;

FIG. 4 is a cross-sectional view illustrating a semiconductor device according to an embodiment of the present inventive concept;

FIGS. 5A to 5G are cross-sectional views illustrating methods of manufacturing a semiconductor device, according to embodiments of the present inventive concept;

FIG. 6 is a cross-sectional view illustrating a semiconductor device according to an embodiment of the present inventive concept.

FIGS. 7A and 7B are cross-sectional views illustrating a semiconductor device according to embodiments of the present inventive concept;

FIG. 8A is a schematic plan layout view illustrating some components of a memory cell region of a semiconductor device according to an embodiment of the present inventive concept;

FIG. 8B is a cross-sectional view taken along line A-A′ of FIG. 8A illustrating a partial configuration according to an embodiment of the present inventive concept;

FIGS. 9A and 9B are cross-sectional views schematically illustrating sonic components of a peripheral region of a semiconductor device according to embodiments of the present inventive concept;

FIGS. 10A to 10C are schematic cross-sectional views of a memory cell region and a peripheral region of semiconductor devices according to embodiments of the present inventive concept;

FIG. 11 is a cross-sectional view illustrating a semiconductor device according to an embodiment of the present inventive concept; and

FIGS. 12A and 12B are enlarged cross-sectional views of region P of FIG. 11 schematically illustrating some components of a semiconductor device according to embodiments of the present inventive concept.

### DETAILED DESCRIPTION OF EMBODIMENTS

Hereinafter, the present inventive concept is described in detail through embodiments with reference to the accompanying drawings.

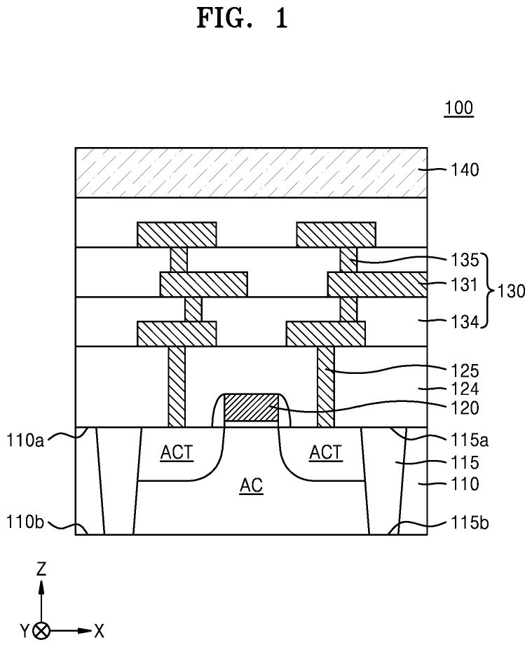

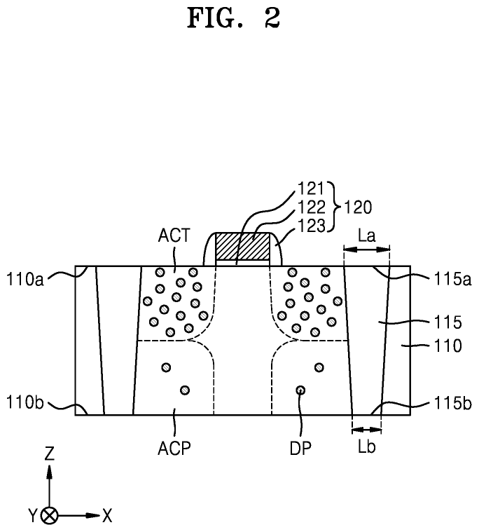

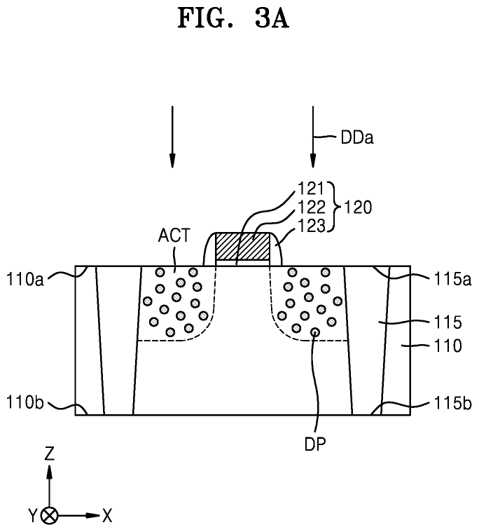

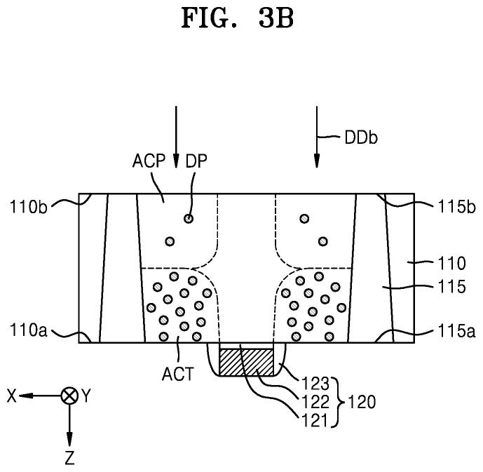

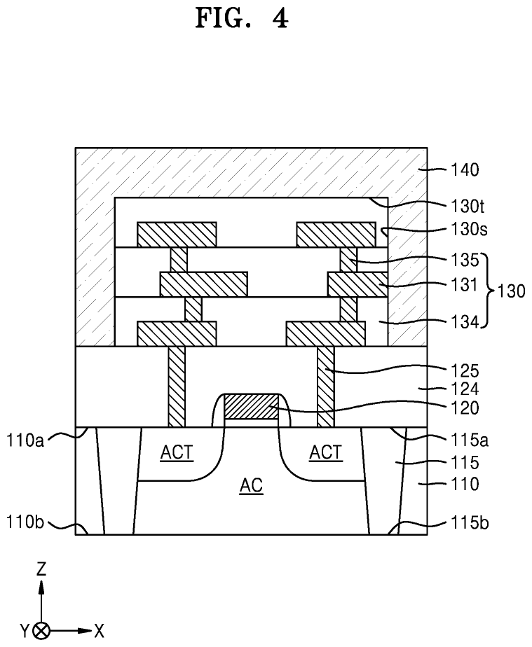

FIG. 1 is a cross-sectional view illustrating a semiconductor device 100 according to an embodiment. FIG. 2 is an enlarged cross-sectional view illustrating only a partial configuration of the semiconductor device 100 shown in FIG. 1 according to an embodiment. FIGS. 3A and 3B are cross-sectional views, in which FIG. 3A illustrates a comparative example of an example illustrated in FIG. 3B according to embodiments. FIG. 4 is a cross-sectional view illustrating a semiconductor device according to embodiments.

Referring to FIGS. 1 and 2, the semiconductor device 100 according to embodiments may include a substrate 110 including a first surface 110a and a second surface 110b opposing each other (e.g., in the Z direction), a device isolation layer 115 extending through the substrate 110 and defining a plurality of active regions AC in the substrate 110, a gate electrode 122 on the first surface 110a of the substrate 110, a wiring structure 130 electrically connected to the gate electrode 122 on the first surface 110a of the substrate 110 and the active region AC, and a protective layer 140 covering the wiring structure 130 and including an insulating material.

In an embodiment, the substrate 110 may include a semiconductor element, such as Si or Ge, or a compound semiconductor, such as SiC, GaAs, InAs, and InP. The substrate 110 may include a semiconductor substrate and structures including at least one insulating layer or at least one conductive region formed on the semiconductor substrate. The conductive region may include, for example, a well doped with an impurity or a structure doped with an impurity.

The device isolation layer 115 defining the active regions AC may be formed in the substrate 110. In an embodiment, the device isolation layers 115 may include an oxide layer, a nitride layer, or combinations thereof. In some embodiments, the device isolation layer 115 may have various structures, such as a shallow trench isolation (STI) structure.

A first surface 115a of the device isolation layer 115 may be positioned to be coplanar with the first surface 110a of the substrate 110 (e.g., in a Z direction), and a second surface 115b of the device isolation layer 115 may be positioned to be coplanar with the second surface 110b of the substrate 110 (e.g., in the Z direction). For example, a thickness of the substrate 110 in a vertical direction (e.g., the Z direction) may be equal to a depth of the device isolation layer 115 in the vertical direction (the Z direction). The first surface 115a of the device isolation layer 115 may be positioned to be coplanar with the first surface 110a of the substrate 110 since the device isolation layer 115 may be formed in a direction from the first surface 110a of the substrate 110 to the second surface 110b of the substrate 110. The first surface 115a of the device isolation layer 115 may be positioned to be coplanar with the first surface 110a. of the substrate 110 since the second surface 110b of the substrate 110 may be formed by removing, for example, grinding, a portion of the substrate 110 so that the second surface 115b of the device isolation layer 115 opposing the first surface 110a of the substrate 110 is exposed. The removing of a portion of the substrate 110 may be referred to as a thinning of the substrate.

A width La of the first surface 115a of the device isolation layer 115 in a first horizontal direction (e.g., an X direction) may be greater than a width Lb of the second surface 115b of the device isolation layer 115 in the first horizontal direction (the X direction). For example, the width La of the first surface 115a of the device isolation layer 115 in the first horizontal direction (the X direction) exposed on the first surface 110a of the substrate 110 may be greater than the width Lb of the second width La of the second surface 115b of the device isolation layer 115 exposed on the second surface 110b of the substrate 110. In an embodiment, the different widths of the device isolation layer 115 on the first surface 110a and second surface 110b may be because the device isolation layer 115 is formed in a direction from the first surface 110a of the substrate 110 toward the second surface 110b of the substrate 110.

The active region AC may include a target doped region ACT positioned between the device isolation layer 115 and the gate electrode 122 (e.g., in the X direction) and including a dopant DP having a first concentration and a path doped region ACP positioned between the device isolation layer 115 and the gate electrode 122, including a dopant DP having a second concentration, less than the first concentration, and extending from the second surface 110b of the substrate 110 to the target doped region ACT. The target doped region ACT may abut the first surface 110a of the substrate 110, and the path doped region ACP may abut the second surface 110b of the substrate 110. For example, the target doped region ACT may be a region positioned between the device isolation layer 115 and the gate electrode 122 in the active region AC and abutting the first surface 110a of the substrate 110. For example, the path doped region ACP may be a region positioned between the device isolation layer 115 and the gate electrode 122 in the active region AC but extending from the second surface 110b of the substrate 110 to the target doped region ACT and may be a region abutting the second surface 110b of the substrate 110.

In some embodiments, the target doped region ACT and the path doped region ACP may include the same type of dopant DP, but the first concentration of the dopant DP included in the target doped region ACT may be higher than the second concentration of the dopant DP included in the path doped region ACP. For example, the target doped region ACT may include a higher concentration of the dopant DP than that of the path doped region ACP. In an embodiment, the higher concentration of dopant DP in the target doped region ACT may be due to a doping process of the target doped region ACT being performed through the second surface 110b of the substrate 110. For example, in a process of implanting the dopant DP in the target doped region ACT, the dopant DP may be implanted into the substrate 110 through the second surface 110b of the substrate 110 and may move in a direction toward the target doped region ACT within the substrate 110. In this process, the dopant DP may remain in the path doped region ACP including a path toward the target doped region ACT. For example, the dopant DP included in the path doped region ACP may be a residual dopant DP in the process of doping the dopant DP into the target doped region ACT.

Specifically, doping profiles of the target doped region ACT and the path doped region ACP are described with reference to FIGS. 3A and 3B. FIGS. 3A and 3B are diagrams illustrating cases in which doping directions are different for the same target doped region ACT.

For example, FIG. 3A shows a comparative embodiment in which a doping process of the target doped region ACT is performed through the first surface 110a of the substrate 110, having a doping direction DDa toward the first surface 110a of the substrate 110 from the outside. In a comparative embodiment in which the first doping direction DDa is towards the first surface 110a of the substrate 110 from the outside, since the target doped region ACT abuts (e.g., directly contacts) the first surface 110a of the substrate 110, the dopant DP may be directly implanted towards the target doped region ACT. For example, there may not be a path region leading to the target doped region ACT, and the dopant DP may be implanted only into the target doped region ACT.

FIG. 3B shows an embodiment of the present inventive concept in which a doping process of the target doped region ACT is performed through the second surface 110b of the substrate 110, having a second doping direction DDb towards the second surface 110b of the substrate 110 from the outside. In an embodiment in which the second doping direction DDb is towards the second surface 110b of the substrate 110 from the outside, the target doped region ACT abuts the first surface 110a and is spaced apart by the thickness of the substrate 110 from the second surface 110b. Accordingly, the dopant may not be directly implanted toward the target doped region ACT, but may have a certain path within the substrate 110. For example, there may be a path region leading to the target doped region ACT, and the dopant DP may remain in the path region to form the path doped region ACP. Accordingly, in some embodiments, the semiconductor device 100 may include the path doped region ACP having a doping concentration, for example, a second concentration, that is less than a doping concentration, for example, a first concentration, of the target doped region ACT.

In the semiconductor device 100 according to an embodiment, since the doping process of the target doped region ACT is performed through the second surface 110b of the substrate 110, the semiconductor device 100 may have increased reliability and performance. In an embodiment, the semiconductor device 100 may comprise a dynamic random-access memory (DRAM) or a NAND FLASH memory device.

In some embodiments, a process excluding the doping process of the target doped region ACT may be performed on the first surface 110a of the substrate 110. Thereafter, the doping process of the target doped region ACT may be performed through the second surface 110b of the substrate 110. The process performed on the first surface 110a of the substrate 110 may include a high-temperature process, and thus, the doping process of the target doped region ACT through the second surface 110b of the substrate 110 may be performed after the high-temperature process. In a comparative embodiment in which the doping process of the target doped region ACT is performed before the high-temperature process is performed, the target doped region ACT may have a doping profile that is changed through the high-temperature process to be different from the initially intended doping profile. For example, the performance of a transistor may change from an intended one during the high-temperature process. In other words, the performance and reliability of the transistor may be increased by performing the doping process of the target doped region ACT through the second surface 110b of the substrate 110 after the high-temperature process.

In some embodiments, when the doping process of the target doped region ACT is performed through the second surface 110b of the substrate 110, the target doped region ACT may be identified using the device isolation layer 115. For example, to perform the doping process of the target doped region ACT, the substrate 110 may be ground to expose the second surface 115b of the device isolation layer 115, and then, the doping process of the target doping region ACT may be performed using the second surface 115b of the device isolation layer 115 as a mark for identifying the target doped region ACT.

In some embodiments, in which the substrate 110 is grinded to use the second surface 115b of the device isolation layer 115 as an identification mark of the target doped region ACT, bending of the semiconductor device 100 may be prevented using a protective layer 140. As described above, the protective layer 140 may protect the semiconductor device 100 from physical impact. Alternatively, for example, the substrate 110 may be turned over to perform the doping process of the target doped region ACT through the second surface 110b of the substrate 110, and in this process, components on the first surface 110a of the substrate 110 may be protected from unwanted external contamination, impact, and electrical signals.

Referring back to FIGS. 1 and 2, in some embodiments, a transistor 120 may be disposed on the first surface 110a of the substrate 110. The transistor 120 may include a gate insulating layer 121, the gate electrode 122, and a spacer 123. The spacer 123 may define a gate trench, and the gate insulating layer 121 and the gate electrode 122 may be sequentially disposed in the gate trench. In an embodiment shown in FIG. 2, it is illustrated that the gate insulating layer 121 is formed only on a bottom surface of the gate trench. However, this is only for convenience of description and embodiments of the present inventive concept are not necessarily limited thereto. For example, in an embodiment the gate insulating layer 121 may be disposed in a cup shape and extend along sidewalls and the bottom surface of the gate trench.

In some embodiments, the semiconductor device 100 may further include an active contact 125 disposed on the first surface 110a of the substrate 110 and electrically connecting the wiring structure 130 to the active region AC. The active contact 125 may be disposed in the interlayer insulating layer 124 filling space between the substrate 110 and the wiring structure 130. In an embodiment, the interlayer insulating layer 124 may include an insulating material that may include silicon oxide, silicon nitride, a low-k material, or combinations thereof. The active contact 125 may electrically connect the wiring structure 130 to the active region AC. For example, the active contact 125 may be electrically connected to the wiring pads 131 in the wiring structure 130 to electrically connect the active region AC to the wiring pads 131. In an embodiment, the active contact 125 may include a conductive material, such as copper (Cu), aluminum (Al), tungsten (W), silver (Ag), gold (Au), or combinations thereof.

In some embodiments, the wiring structure 130 may include an interlayer insulating layer 134 and a plurality of wiring pads 131 and a plurality of wiring contacts 135 disposed in the interlayer insulating layer 134.

In some embodiments, the interlayer insulating layer 134 may include a plurality of insulating layers stacked on the first surface 110a of the substrate 110. In an embodiment shown in FIG. 1, three interlayer insulating layers 134 are illustrated. However, this is only an example, and embodiments of the present inventive concept are not necessarily limited thereto. For example, the number of interlayer insulating layers 134 may vary. In an embodiment, the interlayer insulating layer 134 may include an insulating material including, for example, silicon oxide, silicon nitride, a low-k material, or combinations thereof. In an embodiment, the low-k material may be a material having a lower dielectric constant than that of silicon oxide, for example, phosphosilicate glass (PSG), borophosphosillicate glass (BPSG), fluorosilicate glass (FSG), organosilicate glass (OSG), spin-on-glass (SOG), spin-on-polymer, or combinations thereof.

In some embodiments, the wiring pads 131 may be disposed between the interlayer insulating layers 134. In an embodiment shown in FIG. 1, a plurality of wiring pads 131 is disposed between the three interlayer insulating layers 134. However, this is only an example and embodiments of the present inventive concept are not necessarily limited thereto, and the number of wiring pads 131 may vary. In an embodiment, the wiring pads 131 may include a conductive material that may include copper (Cu), gold (Au), silver (Ag), aluminum (Al), tungsten (W), titanium Ti),(tantalum (Ta), or combinations thereof.

In some embodiments, the wiring contacts 135 may be disposed between the interlayer insulating layers 134. The wiring contacts 135 may electrically connect the wiring pads 131 to one another. In an embodiment, the wiring contacts 135 may include a conductive material, such as copper (Cu), aluminum (Al), tungsten (W), silver (Ag), gold (Au), or combinations thereof.

In some embodiments, the protective layer 140 may be disposed on the wiring structure 130. For example, the protective layer 140 may be disposed to cover an upper surface of the wiring structure 130. The protective layer 140 may be disposed on components of the semiconductor device 100, such as the gate electrode 122 and the wiring structure 130, to cover the components of the semiconductor device 100. In an embodiment, the protective layer 140 may be formed to protect the components disposed on the first surface 110a of the substrate 110 in a subsequent process. For example, the protective layer 140 may protect the components of the semiconductor device 100 from physical impact. In some embodiments, the protective layer 140 may include an insulating material. For example, in an embodiment the protective layer 140 may include an insulating material that may include silicon oxide, silicon nitride, a low-k material, or combinations thereof. For example, the protective layer 140 may protect the components of the semiconductor device 100 from unwanted electrical signals.

Referring to FIG. 4, in an embodiment the protective layer 140 may include a portion surrounding an upper surface 130t and a lateral side surface 130s of the wiring structure 130. Accordingly, the protective layer 140 may protect the lateral side surface 130s as well as the upper surface 130t of the wiring structure 130.

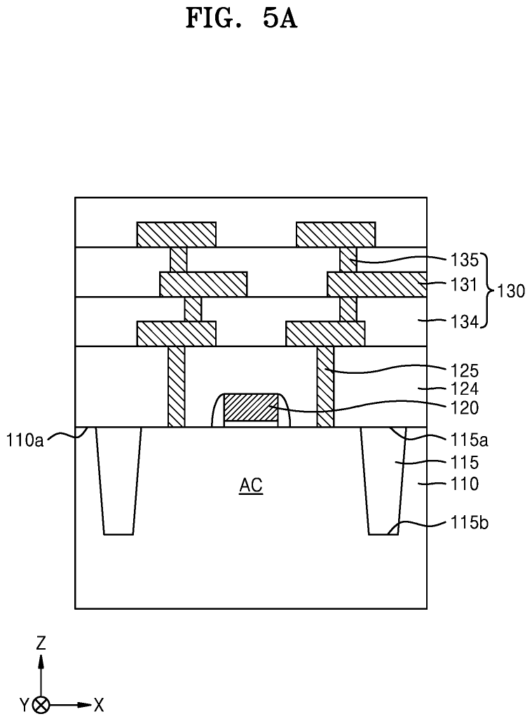

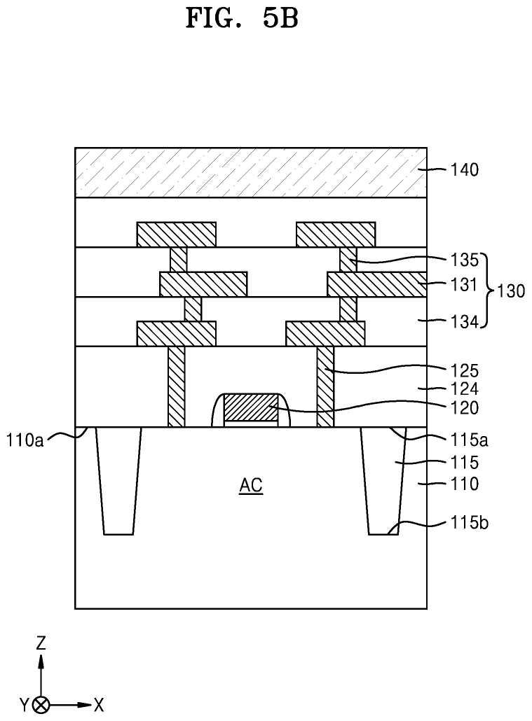

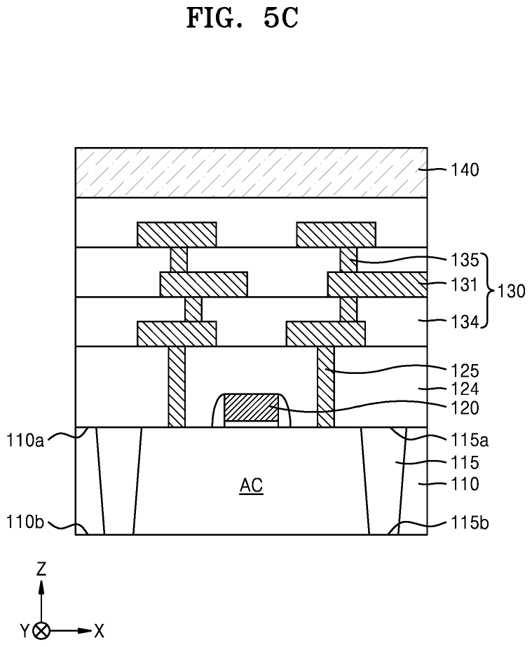

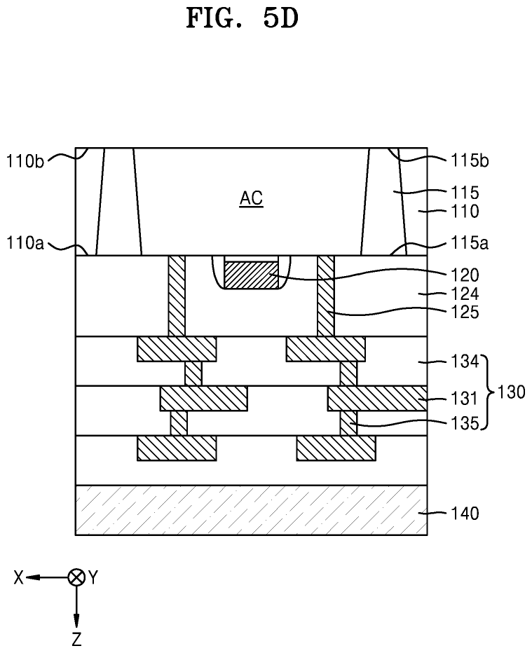

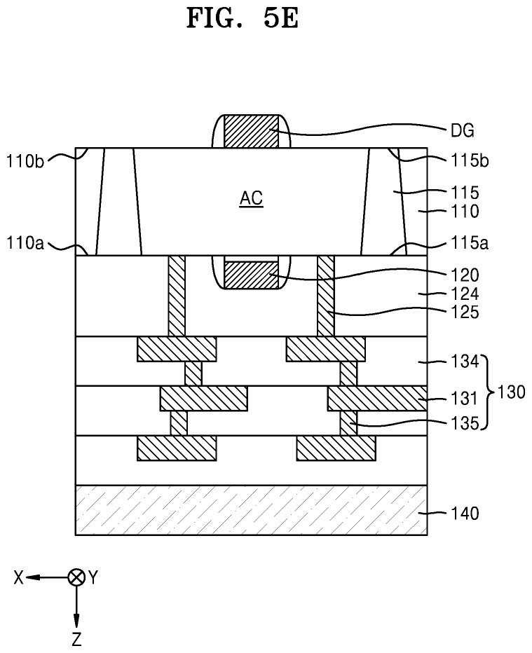

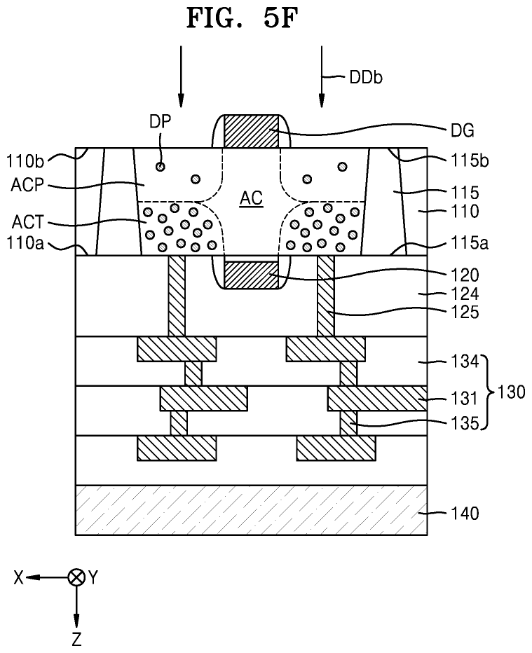

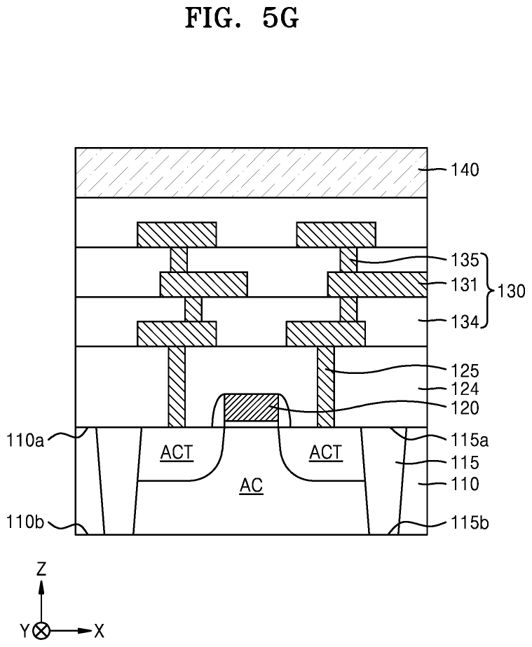

FIGS. 5A to 5G are cross-sectional views illustrating methods of manufacturing a semiconductor device according to embodiments.

Referring to FIG. 5A, the device isolation layer 115 may be disposed in the substrate 110, and the active region AC may be defined by the device isolation layer 115. In an embodiment, the thickness of the substrate 110 in the vertical direction (the Z direction) may be greater than the depth of the device isolation layer 115 in the vertical direction (the Z direction). The first surface 115a of the device isolation layer 115 may be disposed to be coplanar with the first surface 110a of the substrate 110, and the second surface 115b of the device isolation layer 115 may be positioned in the substrate 110 above the second surface 110b of the substrate 110.

The transistor 120 including the gate electrode 122 may be disposed on the first surface 110a of the substrate 110, and the wiring structure 130 electrically connected to the gate electrode 122 on the first surface 110a of the substrate 110 and the active region AC may be disposed thereon.

Referring to FIG. 5B, after a process of forming all components except for a doping process of the active region AC is completed as shown in FIG. 5A, the protective layer 140 covering a resultant structure may be formed. As described above, the protective layer 140 may be formed on (e.g., formed directly thereon) the wiring structure 130 and may be disposed to cover the wiring structure 130. For example, the protective layer 140 may be formed directly on a top surface of the interlayer insulating layer 134.

Referring to FIG. 5C, the second surface 110b may be formed by grinding the substrate 110. As a result, the second surface 115b of the device isolation layer 115 may be positioned to be coplanar with the second surface 110b of the substrate 110. For example, the thickness of the substrate 110 in the vertical direction (the Z direction) may be equal to the depth of the device isolation layer 115 in the vertical direction (the Z direction). Accordingly, the second surface 115b of the device isolation layer 115 may be exposed on the second surface 110b of the substrate 110 to be used as a mark for identifying the active region AC.

Referring to FIG. 5D, a resultant structure of FIG. 5C may be inverted in a vertical direction (the Z direction). Accordingly, the relative positions of the first surface 110a and the second surface 110b of the substrate 110 in the vertical direction (the Z direction) may change. For example, the resultant structure may be inverted so that the second surface 110b is oriented on the top and the protective layer 140 is on the bottom.

Referring to FIG. 5E, a dummy gate DG may be disposed on the second surface 110b of the substrate 110. The dummy gate DG may be formed to perform a doping process of the active region AC. The dummy gate DG may be disposed to partially overlap the gate electrode 122 disposed on the first surface 110a of the substrate 110 in the vertical direction (the Z direction). For example, the dummy gate DG may be disposed to indicate a position of the gate electrode 122 on the second surface 110b of the substrate 110. For example, the dummy gate DG does not actually function as a gate, but may be formed to serve as a mask in the doping process of the active region AC. The dummy gate DG may be formed at a necessary position using the second surface 115b of the device isolation layer 115 exposed on the second surface 110b of the substrate 110 as an identification mark.

Referring to FIG. 5F, a doping process of the target doped region ACT may be performed through the second surface 110b of the substrate 110. As described above, the active region AC may include the target doped region ACT and the path doped region ACP, and as the doping process of the target doped region ACT is performed in the second doping direction DDb through the second surface 110b of the substrate 110, the path doped region ACP leading to the target doped region ACT may also include the dopant DP. For example, the path doped region ACP may include the dopant DP having a second concentration lower than the first concentration of the target doped region ACT.

In some embodiments, the target doped region ACT may be identified through the second surface 115b of the device isolation layer 115 exposed on the second surface 110b of the substrate 110. As described above, the target doped region ACT may be positioned between the device isolation layer 115 and the gate electrode 122, and instead of the gate electrode 122 disposed on the first surface 110a of the substrate 110, the dummy gate DG formed on the second surface 110b of the substrate 110 may serve as a mask in performing the doping. For example, the doping process of the target doped region ACT may be performed using a region between the second surface 115b of the device isolation layer 115 and the dummy gate DG as a target.

Referring to FIG. 5G, after the doping process of the target doped region ACT is completed as shown in FIG. 5F, the dummy gate DG may be removed, and a resultant structure may be inverted in the vertical direction (the Z direction) to manufacture the semiconductor device 100 (refer to FIG. 1) according to an embodiment.

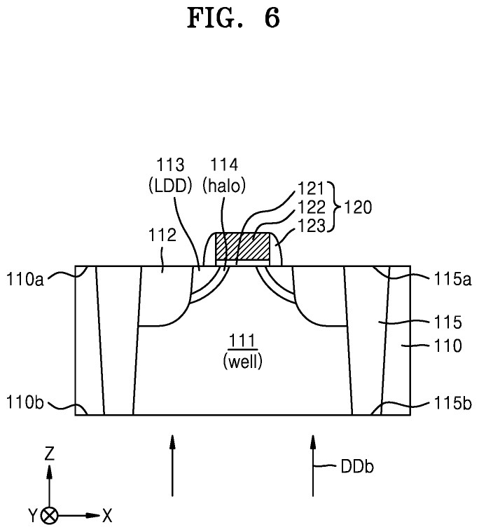

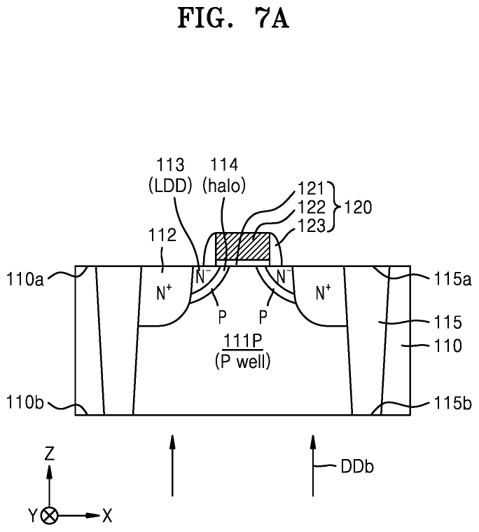

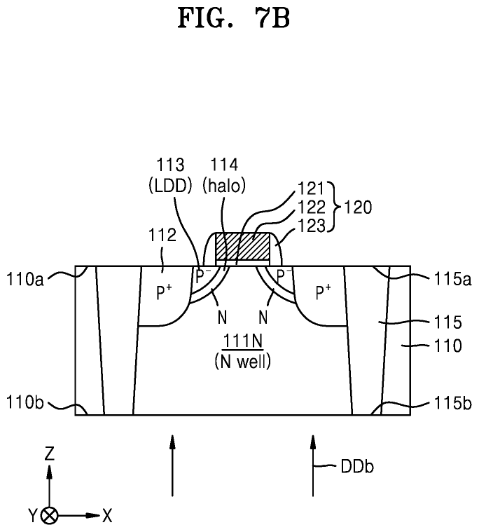

FIG. 6 is a cross-sectional view illustrating a semiconductor device according to an embodiment. FIGS. 7A and 7B are cross-sectional views illustrating a semiconductor device according to embodiments.

Referring to FIG. 6, the active region AC (refer to FIG. 1) may include a first region 111, a second region 112, a third region 113, and a fourth region 114. The first region 111 may include a doped region in the active region AC defined by the device isolation layer 115 and may refer to a portion excluding the second region 112 to the fourth region 114 in the active region AC. The second region 112 may be positioned between the device isolation layer 115 and the gate electrode 122 and may abut the first surface 110a of the substrate 110. The third region 113 may be positioned between the second region 112 and the gate electrode 122 and may abut the first surface 110a of the substrate 110. The fourth region 114 may be positioned between the first region 111 and the third region 113 and may surround the third region 113. For example, in an embodiment the fourth region 114 may surround a lower surface of the third region 113. The fourth region 114 may abut the first surface 110a of the substrate 110.

In some embodiments, the second region 112 and the third region 113 may be doped with a dopant having the same conductivity type. For example, in an embodiment both the second region 112 and the third region 113 may be doped with an N-type dopant or a P-type dopant. In some embodiments, the first region 111 and the fourth region 114 may be doped with a dopant having the same conductivity type. For example, both the first region 111 and the fourth region 114 may be doped with an N-type dopant or a P-type dopant. In some embodiments, the first region 111 and the second region 112 may be doped with dopants having different conductivity types from each other. For example, in an embodiment in which the second region 112 and the third region 113 are doped with an N-type dopant, the first region 111 and the fourth region 114 may be doped with a P-type dopant. Alternatively, in an embodiment in which the second region 112 and the third region 113 are doped with a P-type dopant, the first region 111 and the fourth region 114 may be doped with an N-type dopant.

In some embodiments, the second region 112 and the third region 113 may be doped with different types of dopants having the same conductivity type. For example, even in an embodiment in which both the second region 112 and the third region 113 are doped with an N-type dopant, the second region 112 may be doped with phosphorus (P) while the third region 113 may be doped with arsenic (As). In some embodiments, the first region 111 and the fourth region 114 may be doped with different types of dopants having the same conductivity type. For example, although both the first region 111 and the fourth region 114 are doped with a P-type dopant, the first region 111 may be doped with boron (B), whereas the fourth region 114 may be doped with indium (In). Alternatively, in some other embodiments, the second region 112 and the third region 113 may be doped with the same type of dopant, for example, phosphorus (P), and the first region 111 and the fourth region 114 may be doped with the same type of dopant, for example, boron (B).

In some embodiments, the second region 112 and the third region 113 doped with the dopant having the same conductivity type may be doped with different concentrations. For example, a third doping concentration of the third region 113 may be lower than a second doping concentration of the second region 112. In some embodiments, the first region 111 and the fourth region 114 doped with a dopant having the same conductivity type may be doped with different concentrations. For example, a fourth doping concentration of the fourth region 114 may be higher than a first doping concentration of the first region 111. Alternatively, for example, the fourth doping concentration of the fourth region 114 may be lower than the first doping concentration of the first region 111. However, the first doping concentration to the fourth doping concentration of the first region 111 to the fourth region 114 may be variously selected, and embodiments of the present inventive concept are not necessarily limited to those described above.

In some embodiments, the doping of the first region 111 to the fourth region 114 illustrated in FIG. 6 may be performed through the second surface 110b of the substrate 110. For example, a dopant may be implanted into the first region 111 through the second surface 110b of the substrate 110. In a subsequent doping of the second region 112 to the fourth region 114, a dopant may be implanted through the second surface 110b of the substrate 110. For example, a dopant source implanted in the first region 111 to the fourth region 114 may be located outside the second surface 110b of the substrate 110.

In some embodiments, the semiconductor device may include a lightly doped drain (LDD) halo well structure. For example, the first region 111 may include a well region. For example, the third region 113 may include an LDD region. For example, the third region 113 may be a region in which a dopant is implanted at a lower concentration than that of the second region 112 of the active region AC. The second region 112 and the third region 113 may include a source/drain region of the transistor 120. For example, the fourth region 114 may include a halo region. For example, the fourth region 114 may be a region in which a doping concentration of the substrate 110 at a corner of the source/drain region is locally increased.

In some embodiments, the LDD halo well structure of the semiconductor device according to an embodiment of the present inventive concept may be a structure formed by implanting a dopant in the second doping direction DDb through the second surface 110b of the substrate 110. For example, in an embodiment the well region of the first region 111, the LDD region of the third region 113, and the halo region of the fourth region 114 may be a structure formed by a doping process through the second surface 110b of the substrate 110.

Referring to FIG. 7A, the semiconductor device according to an embodiment of the present inventive concept may include an NMOS transistor. For example, the transistor 120 may include an NMOS transistor, and the gate electrode 122 may include an NMOS gate electrode. In an embodiment, the semiconductor device may include a first region 111P doped with a P-type dopant, a second region 112 and a third region 113 doped with an N-type dopant, and a fourth region 114 doped with a P-type dopant. In some embodiments, the first region 111P may include a P well region. In some embodiments, the third region 113 may include an MD region doped with an N-type dopant having a low concentration compared to the second region 112. In some embodiments, the fourth region 114 may include a halo region doped with a P-type dopant having a high concentration, compared to the first region 111. In some other embodiments, the fourth region 114 may include a halo region doped with a P-type dopant that does not have a high concentration compared to the first region 111.

In some embodiments, the P-type dopant in the first region 111P and the fourth region 114 and the N-type dopant in the second region 112 and the third region 113 may have a structure formed by implanting dopants in the second doping direction DDb through the second surface 110b of the substrate 110.

Referring to FIG. 7B, the semiconductor device according to an embodiment of the present inventive concept may include a PMOS transistor. For example, the transistor 120 may include a PMOS transistor, and the gate electrode 122 may include a PMOS gate electrode. The semiconductor device includes a first region 111N doped with an N-type dopant, a second region 112 and a third region 113 doped with a P-type dopant, and a fourth region 114 doped. with an N-type dopant, in some embodiments, the first region 111N may include an N well region. In some embodiments, the third region 113 may include an LDD region doped with a P-type dopant having a low concentration, compared to the second region 112. In some embodiments, the fourth region 114 may include a halo region doped with an N-type dopant having a high concentration compared to the first region 111N. In some other embodiments, the fourth region 114 may include a halo region doped with an N-type dopant not having a high concentration, compared to the first region 111N. In some embodiments, the first region 111N may include an N well region formed in the substrate 110 doped with a P-type dopant.

In some embodiments, the N-type dopant in the first region 111N and the fourth region 114 and the P-type dopant in the second region 112 and the third region 113 may be a structure formed by implanting a dopant in the second doping direction DDb through the second surface 110b of the substrate 110.

For example, in some embodiments, the doping process for forming the LDD halo well structure of the NMOS transistor and/or the PMOS transistor illustrated in FIGS. 7A and 7B may be performed in the second doping direction DDb through the second surface 110b of the substrate 110.

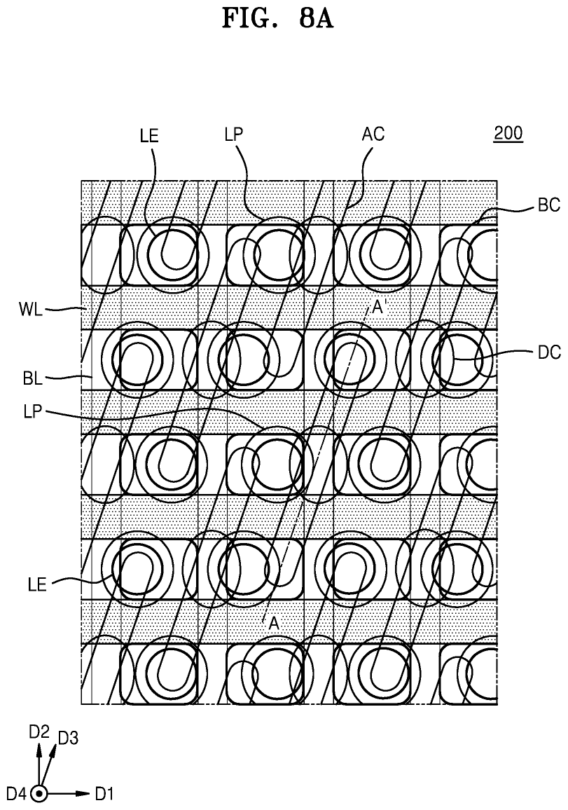

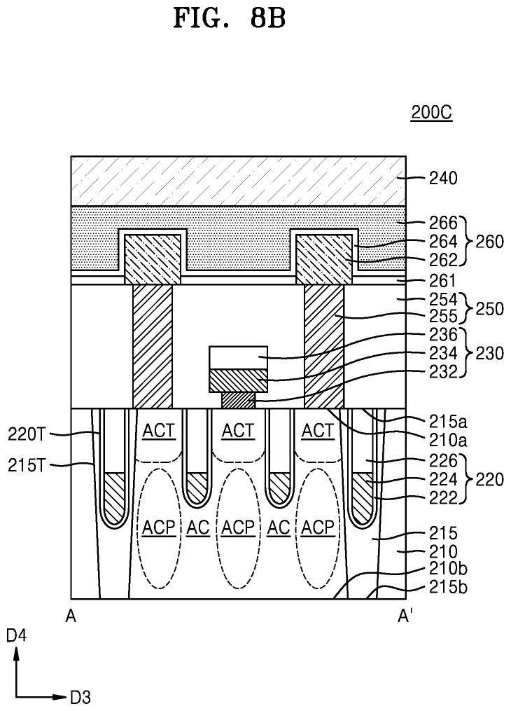

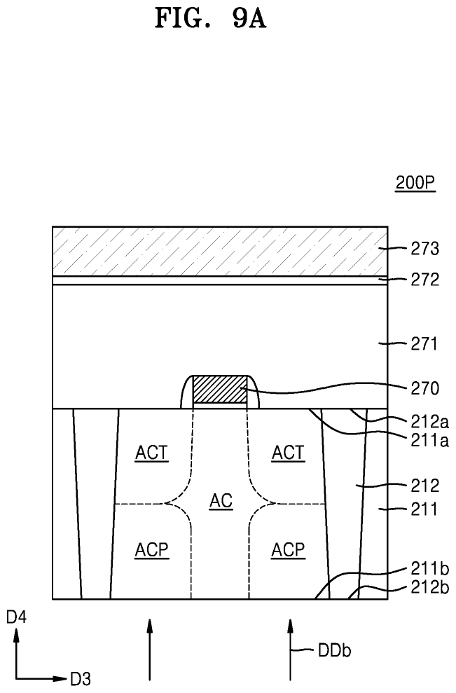

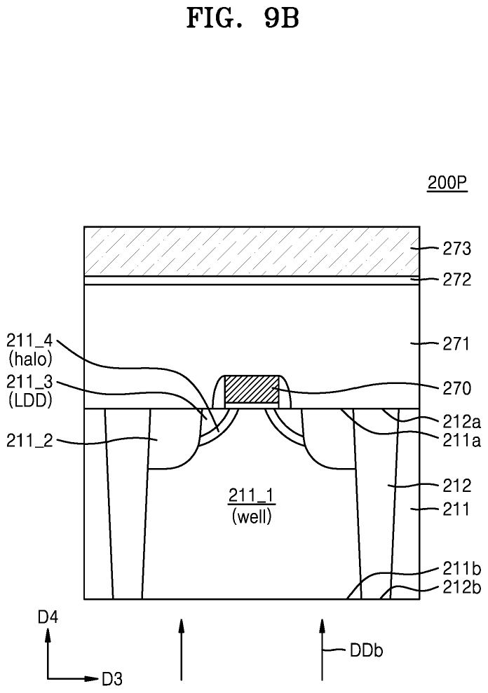

FIG. 8A is a schematic plan layout, view illustrating some components of a memory cell region of a semiconductor device 200 according to an embodiment. FIG. 8B is a cross-sectional view taken along line A-A′ of FIG. 8A illustrating a partial configuration, schematically illustrating a partial configuration of a semiconductor device 200C in a cell region. FIGS. 9A and 9B are cross-sectional views schematically illustrating some components of a peripheral region of a semiconductor device 200P according to embodiments.

Referring to FIG. 8A, the semiconductor device 200 may include a plurality of active regions AC arranged to horizontally extend in a diagonal direction D3 with respect to a first horizontal direction D1 and a second horizontal direction D2 on a plane. A plurality of word lines WL may extend to be parallel to each other in the first horizontal direction D1 across the active regions AC. A plurality of bit lines BL may extend to be parallel to each other in the second horizontal direction D2 intersecting with the first horizontal direction D1 on the word lines WL. For example, in an embodiment the second horizontal direction D2 may be orthogonal to the first horizontal direction D1. Each of the bit lines BL may be connected to the active region AC through a direct contact DC.

A plurality of buried contacts BC may be disposed between two adjacent bit lines BL among the bit lines BL. A plurality of conductive landing pads LP may be respectively arranged on the buried contacts BC. For example, the conductive landing pads LP may be positioned to at least partially overlap the buried contacts BC, respectively (e.g., in a vertical direction D4). A plurality of lower electrodes LE may be respectively arranged on the conductive landing pads LP to be spaced apart from each other. The lower electrodes LE may be respectively connected to the active regions AC through the buried contacts BC and the conductive landing pads LP.

Referring to FIGS. 8A, 8B, 9A and 9B together, the semiconductor devices 200C and 200P may include a substrate including first and second surfaces opposing each other (e.g., in a vertical direction D4), a device isolation layer extending through the substrate in a vertical direction (e.g., D4) and defining an active region in the substrate, a gate electrode structure extending in the first horizontal direction D1 within the substrate, a wiring structure on the substrate, and a protective layer covering the wiring structure and including an insulating material.

For example, as illustrated in FIG. 8B, the substrate of the semiconductor device 200C may include a cell region substrate 210, the active region may include a cell active region AC, the device isolation layer may include a cell device isolation layer 215 disposed in the cell region substrate 210 and defining the cell active region AC, the gate electrode may include a cell gate electrode 224 disposed in the cell region substrate 210, the wiring structure includes a cell wiring structure 250 disposed on the cell region substrate 210, and the semiconductor device 200C may further include a cell capacitor structure 260 disposed on the cell wiring structure 250 and electrically connected to the cell active region AC in the cell region substrate 210.

The cell region substrate 210 may include the cell active region AC defined by the cell device isolation layer 215. In an embodiment, the cell region substrate 210 may be a water including silicon (Si). For example, in some embodiments, the cell region substrate 210 may be a wafer including a semiconductor element, such as germanium (Ge), or a compound semiconductor, such as silicon carbide (SiC), gallium arsenide (GaAs), indium arsenide (InAs), or indium phosphide (InP). In an embodiment, the cell region substrate 210 may have a silicon on insulator (SCT) structure. In addition, the cell region substrate 210 may include a conductive region, for example, a well doped with an impurity or a structure doped with an impurity.

In an embodiment, the cell device isolation layer 215 may have, for example, an STI structure. The cell device isolation layer 215 may include an insulating material filling a device isolation trench formed in the cell region substrate 210. In an embodiment, the insulating material may include fluoride silicate glass (FSG), undoped silicate glass (USG), boro-phospho-silicate glass (BPSG), phospho-silicate glass (PSG), flowable oxide (FOX), plasma enhanced tetra-ethyl-ortho-silicate (PE-TEOS) or tonen silazene (TOSZ). However, embodiments of the present inventive concept are not necessarily limited thereto.

A first surface 215a of the cell device isolation layer 215 may be positioned to be coplanar with a first surface 210a of the cell region substrate 210, and a second surface 215b of the cell device isolation layer 215 may be positioned to be coplanar with a second surface 210b of the cell region substrate 210. For example, a thickness of the cell region substrate 210 in a vertical direction D4 may be equal to a depth of the cell device isolation layer 215 in the vertical direction D4. In an embodiment, the first surface 215a of the cell device isolation layer 215 may be positioned to be coplanar with the first surface 210a of the cell region substrate 210 based on the cell device isolation layer 215 being formed in a direction from the first surface 210a of the cell region substrate 210 toward the second surface 210b of the cell region substrate 210. The second surface 215b of the cell device isolation layer 215 may be positioned to be coplanar with the second surface 210b of the cell region substrate 210 based on the second surface 210b of the cell region substrate 210 being formed by grinding the surface opposing the first surface 210a of the cell region substrate 210 so that the second surface 215b of the cell device isolation layer 215 is exposed.

In an embodiment, a width of the first surface 215a of the cell device isolation layer 215 in the horizontal direction may be greater than a width of the second surface 215b of the cell device isolation layer 215 in the horizontal direction. For example, the width of the first surface 215a of the cell device isolation layer 215 in the horizontal direction (e.g., D3) exposed on the first surface 210a of the cell region substrate 210 may be greater than the width of the second surface 215b of the cell device isolation layer 215 in the horizontal direction (e.g., D3) exposed on the second surface 210b of the cell region substrate 210. For example, a width of the first surface 215a of the cell device isolation layer 215 in the horizontal direction D3 in which the cell active region AC extends may be greater than a width of the second surface 215b of the cell device isolation layer 215 in the horizontal direction D3.

The cell active region AC may have a relatively long island shape. As illustrated, a major axis of the cell active region AC may be arranged in the direction D3 parallel to an upper surface of the cell region substrate 210. In an embodiment, the cell active region AC may be doped with P-type or N-type dopants.

A source/drain region may be disposed on the cell active region AC located on both sides of the cell gate electrode trench 220T. The source/drain region may be an impurity region doped with an impurity of a conductivity type different from that of the impurity doped in the cell active region AC. The source/drain region may be doped with N-type or P-type impurities.

The cell active region AC may include a target doped region ACT positioned between the cell device isolation layer 215 and the cell gate electrode 224 and including a dopant having a first concentration and a path doped region ACP disposed between the cell device isolation layer 215 and the cell gate electrode 224, including a dopant having a second concentration less than the first concentration, and extending from the second surface 210b of the cell region substrate 210 to the target doped region ACT. The target doped region ACT may include the source/drain region. The target doped region ACT may abut the first surface 210a of the cell region substrate 210, and the path doped region ACP may abut the second surface 210b of the cell region substrate 210. For example, the target doped region ACT may be a region positioned between the cell device isolation layer 215 and the cell gate electrode 224 in the cell active region AC and abutting the first surface 210a of the cell region substrate 210. For example, the path doped region ACP may be a region positioned between the cell device isolation layer 215 and the cell gate electrode 224 in the cell active region AC but extending from the second surface 210b of the cell region substrate 210 to the target doped region ACT. The path doped region AC may be a region abutting the second surface 210b of the cell region substrate 210.

In some embodiments, the target doped region ACT and the path doped region ACP may include the same type of dopant, but the first concentration of the dopant included in the target doped region ACT may be higher than the second concentration of the dopant included in the path doped region ACP. For example, the target doped region ACT may include a higher concentration of dopant than that of the path doped region ACP. The higher concentration of the dopant in the target doped region ACT as compared to the path doped region ACP may be because a doping process of the target doped region ACT is performed through the second surface 210b of the cell region substrate 210. For example, in the process of implanting the dopant into the target doped region ACT, the dopant may be implanted into the cell region substrate 210 through the second surface 210b of the cell region substrate 210 and may move in a direction toward the target doped region ACT in the cell region substrate 210. In this process, the dopant may remain in the path doped region ACP including a path toward the target doped region ACT. For example, the dopant included in the path doped region ACP may be a residual dopant in the process of doping the dopant into the target doped region ACT.

The cell region substrate 210 may include the cell gate electrode trench 220T extending in the first horizontal direction D1. The cell gate electrode trench 220T may intersect with the cell active region AC and may be formed to have a certain depth from the first surface 210a of the cell region substrate 210. A portion of the cell gate electrode trench 220T may extend into the cell device isolation layer 215. In an embodiment, the cell gate electrode trench 220T formed in the cell device isolation layer 215 may have a bottom surface located at a level lower than that of the cell gate electrode trench 220T formed in the cell active region AC.

A cell gate electrode structure 220 may be formed in the cell gate electrode trench 220T. The cell gate electrode structure 220 may include a cell gate insulating layer 222, a cell gate electrode 224, and a cell gate capping layer 226 sequentially formed on an inner wall of the cell gate electrode trench 220T. The cell gate electrode structure 220 may include the word line WL of FIG. 8A.

The cell gate insulating layer 222 may be conformally formed on the inner wall of the cell gate electrode trench 220T to have a certain thickness. In an embodiment, the cell gate insulating layer 222 may include at least one compound selected from silicon oxide, silicon nitride, silicon oxynitride, oxide/nitride/oxide (ONO), and a high-k material having a higher dielectric constant than that of silicon oxide.

The cell gate electrode 224 may be formed on the cell gate insulating layer 222 to fill a portion of the cell gate electrode trench 220T from the bottom of the cell gate electrode trench 220T. In an embodiment, the cell gate electrode 224 may include a work function control layer disposed on the cell gate insulating layer 222 and a buried metal layer filling the bottom portion of the cell gate electrode trench 220T on the work function control layer.

The cell gate capping layer 226 may fill a remaining portion of the cell gate electrode trench 220T on the cell gate electrode 224. For example, in an embodiment the cell gate capping layer 226 may include at least one compound selected from silicon oxide, silicon oxynitride, and silicon nitride.

The cell wiring structure 250 may include a bit line structure 230 extending in the second horizontal direction D2 orthogonal to the first horizontal direction D1 on the cell gate electrode 224. The bit line structure 230 may include a bit line contact 232, a bit line 234, and a bit line capping layer 236 sequentially stacked on the cell region substrate 210 (e.g., in the vertical direction D4). The bit line structure 230 may include the bit line BL of FIG. 8A. For example, in an embodiment the bit line contact 232 may include polysilicon, the bit line 234 may include a metal material, and the bit line capping layer 236 may include silicon nitride or silicon oxynitride.

The cell wiring structure 250 may be disposed on the cell region substrate 210. The cell wiring structure 250 may include an interlayer insulating layer 254 and a contact structure 255 disposed in the interlayer insulating layer 254. The interlayer insulating layer 254 may be disposed on the cell region substrate 210, and the bit line contact 232 may pass through the interlayer insulating layer 254 to be connected to the source/drain region. For example, the bit line contact 232 may be connected to the target doped region ACT of the cell active region AC. The bit line 234 and the bit line capping layer 236 may be disposed in the interlayer insulating layer 254. The interlayer insulating layer 254 may cover lateral side surfaces and upper surfaces of the bit line 234 and the bit line capping layer 236. In an embodiment, the interlayer insulating layer 254 may include a first interlayer insulating layer disposed on the cell region substrate 210 and through which the bit line contact 232 is formed and a second interlayer insulating layer disposed on the first interlayer insulating layer and covering the side surfaces and upper surfaces of the bit line 234 and the bit line capping layer 236. However, embodiments of the present inventive concept are not necessarily limited thereto.

The contact structure 255 may be disposed on the source/drain region. For example, the contact structure 255 may be disposed on the target doped region ACT of the cell active region AC. The interlayer insulating layer 254 may surround a sidewall of the contact structure 255. In some embodiments, the contact structure 255 may include a lower contact, a metal silicide layer, and an upper contact sequentially stacked on the cell region substrate 210 (e.g., in the vertical direction D4). However, embodiments of the present inventive concept are not necessarily limited thereto.

In some embodiments, the protective layer 240 may be disposed on the cell wiring structure 250. For example, the protective layer 240 may be disposed to cover an upper surface of the cell wiring structure 250, such as an upper surface of an upper electrode 266. The protective layer 240 may be disposed on components of the semiconductor device 200C, such as the cell gate electrode 224 and the cell wiring structure 250, to cover the components. The protective layer 240 may be formed to protect components disposed on the first surface 210a of the cell region substrate 210 in a subsequent process. For example, the protective layer 240 may protect the components of the semiconductor device 200C from physical impact. In some embodiments, the protective layer 240 may include an insulating material. For example, in an embodiment the protective layer 240 may include an insulating material that may include silicon oxide, silicon nitride, a low-k material, or combinations thereof. For example, the protective layer 240 may protect the components of the semiconductor device 200C from unwanted electrical signals.

In some embodiments, the protective layer 240 may include portions surrounding the upper surface and lateral side surfaces of the cell wiring structure 250. Accordingly, the protective layer 240 may protect not only the upper surface but also the lateral side surface of the cell wiring structure 250.

The cell capacitor structure 260 may include a lower electrode 262 electrically connected to the contact structure 255, a dielectric layer 264 conformally covering the lower electrode 262, and an upper electrode 266 on the dielectric layer 264. For example, the lower electrode 262 may be disposed directly on an upper surface of the contact structure 255 and the dielectric layer 264 may cover an upper surface and a portion of the lateral sides of the lower electrode 262. In an embodiment, an etch stop layer 261 including an opening may be formed on the interlayer insulating layer 254, and a bottom portion of the lower electrode 262 may be disposed in the opening of the etch stop layer 261. The dielectric layer 264 may directly contact an upper surface of the etch stop layer 261.

In an embodiment in which the semiconductor device 200C further includes the cell capacitor structure 260, the protective layer 240 may be disposed on the cell capacitor structure 260. For example, the protective layer 240 may be disposed to cover an upper surface of the cell capacitor structure 260 to protect the components of the semiconductor device 200C including the cell capacitor structure 260. In some embodiments, the protective layer 240 may include portions surrounding the upper and lateral side surfaces of the cell capacitor structure 260.

Referring to FIG. 9A, a substrate of the semiconductor device 200P may include a peripheral region substrate 211, an active region may include a peripheral active region AC, a device isolation layer may include a peripheral device isolation layer 212 disposed on the peripheral region substrate 211 and defining the peripheral active region AC, a gate electrode may include a peripheral gate electrode 270 disposed on the peripheral region substrate 211, and a wiring structure may include a peripheral wiring structure 271 disposed on the peripheral region substrate 211. An etch stop layer 272 may be disposed on the peripheral wiring structure 271.

The peripheral region substrate 211 may include the peripheral active region AC defined by the peripheral device isolation layer 212. The peripheral device isolation layer 212 may have, for example, an STI structure. The peripheral device isolation layer 212 may include an insulating material filling a device isolation trench formed in the peripheral region substrate 211.

A first surface 212a of the peripheral device isolation layer 212 may be disposed to be coplanar with a first surface 211a of the peripheral region substrate 211, and a second surface 212b of the peripheral device isolation layer 212 may be disposed to be coplanar with a second surface 211b of the peripheral region substrate 211. For example, a thickness of the peripheral region substrate 211 in the vertical direction D4 may be equal to a depth of the peripheral device isolation layer 212 in the vertical direction D4. In an embodiment, the first surface 212a of the peripheral device isolation layer 212 is disposed to be coplanar with the first surface 211a of the peripheral region substrate 211 due to the peripheral device isolation layer 212 being formed in a direction from the first surface 211a of the peripheral region substrate 211 towards the second surface 211b. The second surface 212b of the peripheral device isolation layer 212 is disposed to be coplanar with the second surface 211b of the peripheral region substrate 211 due to the second surface 211b of the peripheral region substrate 211 being formed by grinding a surface opposing the first surface 211a of the peripheral device isolation layer 212 so that the second surface 212b is exposed.

In an embodiment, a width of the first surface 212a of the peripheral device isolation layer 212 in a horizontal direction (e.g., D3) may be greater than a width of the second surface 212b of the peripheral device isolation layer 212 in the horizontal direction. For example, the width of the first surface 212a of the peripheral device isolation layer 212 in the horizontal direction exposed on the first surface 211a of the peripheral region substrate 211 may be greater than the width of the second surface 212b of the peripheral device isolation layer 212 in the horizontal direction exposed on the second surface 211b of the peripheral region substrate 211. For example, the width of the first surface 212a of the peripheral device isolation layer 212 in the direction D3 in which the peripheral active region AC extends may be greater than the width of the second surface 212b of the peripheral device isolation layer 212 in the direction D3.

The peripheral active region AC may include a target doped region ACT positioned between the peripheral device isolation layer 212 and the peripheral gate electrode 270 and including a dopant having a first concentration and a path doped region ACP positioned between the peripheral device isolation layer 212 and the peripheral gate electrode 270, including a dopant having a second concentration less than the first concentration, and extending from the second surface 211b of the peripheral region substrate 210 to the target doped region ACT. In some embodiments, the first concentration of the target doped region ACT and the second concentration of the path doped region ACP of the semiconductor device 200P may be different from the first concentration of the target doped region ACT and the second concentration of the path doped region ACP of the semiconductor device 200C. The target doped region ACT may include source/drain regions. The target doped region ACT may abut the first surface 211a of the peripheral region substrate 211, and the path doped region ACP may abut the second surface 211b of the peripheral region substrate 211. For example, the target doped region ACT may be a region positioned between the peripheral device isolation layer 212 and the peripheral gate electrode 270 in the peripheral active region AC and abutting the first surface 211a of the peripheral region substrate 211. For example, the path doped region ACP may be a region located between the peripheral device isolation layer 212 and the peripheral gate electrode 270 in the peripheral active region AC but may be a region ranging from the second surface 211b of the peripheral region substrate 211 to the target doped region ACT. The path doped region ACP may abuts the second surface 211b of the peripheral region substrate 211.

In some embodiments, the target doped region ACT and the path doped region ACP may include the same type of dopant, but the first concentration of the dopant included in the target doped region ACT may be higher than the second concentration of the dopant included in the path doped region ACP. For example, the target doped region ACT may include a higher concentration of dopant than the path doped region ACP. In an embodiment, the higher concentration of dopant in the target doped region ACT may be due to the performing of the doping process of the target doped region ACT in the second doping direction DDb through the second surface 211b of the peripheral region substrate 211. For example, in the process of implanting the dopant into the target doped region ACT, the dopant may be implanted into the peripheral region substrate 2121 in the second doping direction DDb through the second surface 211b of the peripheral region substrate 211 and may move in a direction towards the target doped region ACT within the peripheral region substrate 211. In this process, the dopant may remain in the path doped region ACP including a path toward the target doped region ACT. For example, the dopant included in the path doped region ACP may be a residual dopant in the process of doping the dopant into the target doped region ACT.

In some embodiments, the protective layer 273 may be disposed on the peripheral wiring structure 271. For example, the protective layer 273 may be disposed to cover an upper surface of the peripheral wiring structure 271. In an embodiment, the protective layer 273 may be disposed directly on an upper surface of the etch stop layer 272. The etch stop layer 272 may be disposed directly on an upper surface of the peripheral wiring structure 271. The protective layer 273 may be disposed on the components of the semiconductor device 200P, such as the peripheral gate electrode 270 and the peripheral wiring structure 271, to cover the components. The protective layer 273 may be formed to protect the components disposed on the first surface 211a of the peripheral region substrate 211 in a subsequent process. For example, the protective layer 273 may protect the components of the semiconductor device 200P from physical impact. In some embodiments, the protective layer 273 may include an insulating material. For example, the protective layer 273 may protect the components of the semiconductor device 200P from unwanted electrical signals.

In some embodiments, the protective layer 273 may include portions surrounding upper and lateral side surfaces of the peripheral wiring structure 271. Accordingly, the protective layer 273 may protect the lateral side surface as well as the upper surface of the peripheral wiring structure 271.

Referring to FIG. 9B, the active region AC of the semiconductor device 200P may include a first region 211_1, a second region 211_2, a third region 211_3, and a fourth region 211_4. The first region 211_1 may include a doped region in the peripheral active region AC defined by the peripheral device isolation layer 212, and may refer to a portion excluding the second region 211_2 to fourth region 211_4 in the peripheral active region AC. The second region 211_2 may be disposed between the peripheral device isolation layer 212 and the peripheral gate electrode 270, and may abut the first surface 211a of the peripheral region substrate 211. The third region 211_3 may be disposed between the second region 211_2 and the gate electrode 122 and may abut the first surface 211a of the peripheral region substrate 211. The fourth region 211_4 may be disposed between the first region 211_1 and the third region 211_3 and surround the third region 211_3. The fourth region 211_4 may abut the first surface 211a of the peripheral region substrate 211.

In some embodiments, the second region 211_2 and the third region 211_3 may be doped with a dopant having the same conductivity type. In some embodiments, the first region 211_1 and the fourth region 211_4 may be doped with a dopant having the same conductivity type. In some embodiments, the first region 211_1 and the second region 211_2 may be doped with dopants having different conductivity types.

In some embodiments, the second region 211_2 and the third region 211_3 doped with a dopant having the same conductivity type may be doped to have different concentrations. For example, in an embodiment a third doping concentration of the third region 211_3 may be less than a second doping concentration of the second region 211_2. In some embodiments, the first region 211_1 and the fourth region 211_4 doped with a dopant having the same conductivity type may be doped to have different concentrations. For example, in an embodiment a fourth doping concentration of the fourth region 211_4 may be higher than a first doping concentration of the first region 211_1. Alternatively, for example, the fourth doping concentration of the fourth region 211_4 may be lower than the first doping concentration of the first region 211_1. In some embodiments, the first doping concentration to the fourth doping concentration of the first region 211_1 to the fourth region 211_4. However, embodiments of the present inventive concept are not necessarily limited thereto and the concentrations of the first to fourth regions 211_1 to 211_4 may be variously selected. In some embodiments, the first doping concentration to the fourth doping concentration of the first region 211_1 to the fourth region 211_4 of the semiconductor device 200P may be different from the first doping concentration to the fourth doping concentration of the first region 111 to the fourth region 114 of the semiconductor device 100.

In some embodiments, the doping of the first region 211_1 to the fourth region 211_4 illustrated in FIG. 9B may be performed in the second doping direction DDb through the second surface 211b of the peripheral region substrate 211. For example, a dopant may be implanted into the first region 211_1 through the second surface 211b of the peripheral region substrate 211. A dopant may be implanted in the second doping direction DDb through the second surface 211b of the peripheral region substrate 211 in a subsequent doping of the second region 211_2 to the fourth region 211_4. For example, a dopant source implanted in the first region 211_1 to the fourth region 211_4 may be disposed outside the second surface 211b of the peripheral region substrate 211.

The semiconductor device 200P according to an embodiment of the present inventive concept may include an LDD halo well structure. The first region 211_1 may include a well region. The third region 211_3 may include an LDD region. For example, the third region 211_3 may be a region in which a dopant is implanted to be weaker than that of the second region 211_2 of the active region AC. The second region 211_2 and the third region 211_3 may include a source/drain region of the transistor 120 The fourth region 211_4 may include a halo region. For example, the fourth region 211_4 may be a region in which a doping concentration of the peripheral region substrate 211 at a corner portion of the source/drain region is locally increased,

In some embodiments, the LDD halo well structure of the semiconductor device 200P may be a structure formed by implanting a dopant in the second doping direction DDb through the second surface 211b of the peripheral region substrate 211. For example, the well region of the first region 211_1, the LDD region of the third region 211_3, and the halo region of the fourth region 211_4 may be a structure formed by a doping process through the second surface 211b of the peripheral region substrate 211.

The description of the first region 211_1 to the fourth region 211_4 of the semiconductor device 200P may include descriptions the same as or similar to those for the first region 111 to the fourth region 114 of the semiconductor device 100 with reference to FIG. 6 and a repeated description is omitted for economy of description.

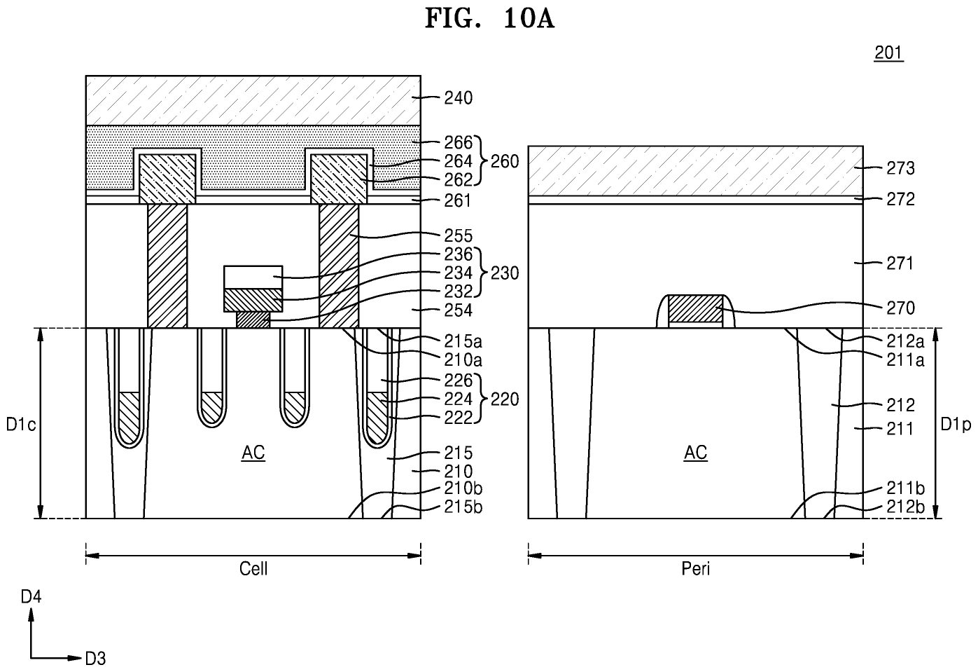

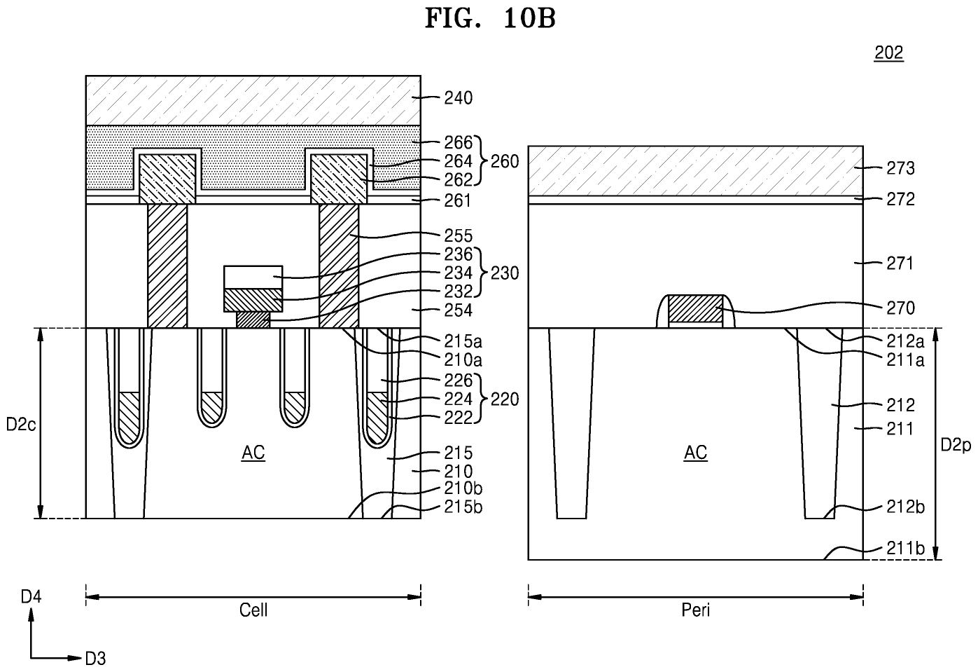

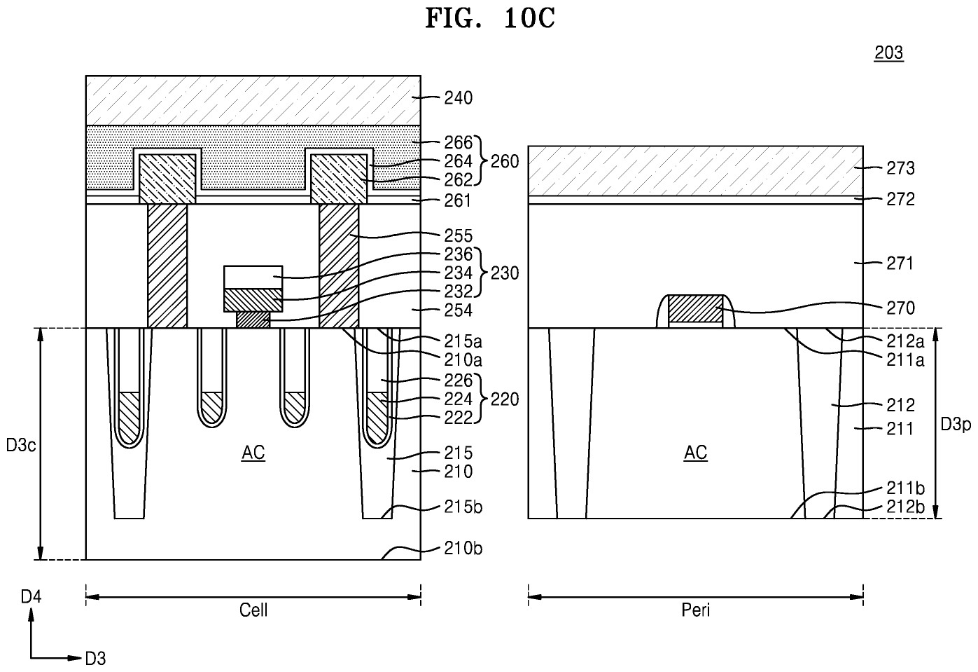

FIGS. 10A to 10C are schematic cross-sectional views of a memory cell region and a peripheral region of semiconductor devices 201, 202, and 203 according to embodiments. The semiconductor devices 201, 202, and 203 of FIGS. 10A to 10C may include at least one of the semiconductor devices 200, 200P and 200C of FIGS. 8A, 8B, 9A, and 9B.

Referring to FIG. 10A, the semiconductor device 201 according to an embodiment may include the semiconductor device 200C illustrated in FIG. 8B and the semiconductor device 200P illustrated in FIG. 9A. For example, the cell region substrate 210 of the semiconductor device 201 may include the cell active region AC defined by the cell device isolation layer 215, the first surface of the cell device isolation layer 215 may be positioned to be coplanar with the first surface 210a of the cell region substrate 210, and the second surface 215b of the cell device isolation layer 215 may be positioned to be coplanar with the second surface 210b of the cell region substrate 210. For example, the peripheral region substrate 211 of the semiconductor device 201 may include the peripheral active region AC defined by the peripheral device isolation layer 212, and the first surface of the peripheral device isolation layer 212 may be positioned to be coplanar with the first surface 211a of the peripheral region substrate 211, and the second surface 212b of the peripheral device isolation layer 212 may be positioned to be coplanar with the second surface 211b of the peripheral region substrate 211.

In some embodiments, a thickness of the cell region substrate 210 of the semiconductor device 201 in the vertical direction D4 may be D1c, and a thickness of the peripheral region substrate 211 in the vertical direction D4 may be D1p. In an embodiment, when the cell region substrate 210 and the peripheral region substrate 211 are ground at the same level, the thickness D1c of the cell region substrate 210 may be substantially equal to the thickness D1p of the peripheral region substrate 211.

In some embodiments, in the semiconductor device 201 in which the thickness D1c of the cell region substrate 210 is substantially equal to the thickness D1p of the peripheral region substrate 211, implanting in the second surface 210b of the cell region substrate 210 and implanting in the second surface 211b of the peripheral region substrate 211 may be equally performed to form doped regions having the same depth.

Referring to FIG. 10B, the semiconductor device 202 according to an embodiment may include the semiconductor device 200C illustrated in FIG. 8B. For example, the memory cell region substrate 210 of the semiconductor device 202 may include the cell active region AC defined by the cell device isolation layer 215, the first surface 215a of the cell device isolation layer 215 may be positioned to be coplanar with the first surface 210a of the cell region substrate 210, and the second surface 215b of the cell device isolation layer 215 may be positioned to be coplanar with the second surface 210b of the cell region substrate 210. In an embodiment, the peripheral region substrate 211 of the semiconductor device 202 may include the peripheral active region AC defined by the peripheral device isolation layer 212, and the first surface 212a of the peripheral device isolation layer 212 may be positioned to be coplanar with the first surface 211a of the peripheral region substrate 211, but the second surface 212b of the peripheral device isolation layer 212 may not be positioned to be coplanar with the second surface 211b of the peripheral region substrate 211. For example, the second surface 212b of the peripheral device isolation layer 212 of the semiconductor device 202 may be disposed in the peripheral region substrate 211 and may be positioned at a vertical level higher than the second surface 211b of the peripheral region substrate 211.

In some embodiments, a thickness of the cell region substrate 210 of the semiconductor device 202 in the vertical direction D4 may be D2c, and a thickness of the peripheral region substrate 211 in the vertical direction D4 may be D2p. By performing grinding of the cell region substrate 210 and the peripheral region substrate 211 at different levels, the thickness D2c of the cell region substrate 210 may be less than the thickness D2p of the peripheral region substrate 211.

In some embodiments, in the semiconductor device 202 in which the thickness D2c of the cell region substrate 210 is different from the thickness D2p of the peripheral region substrate 211, implanting on the second surface 210b of the cell region substrate 210 and implanting on the second surface 211b of the peripheral region substrate 211 may be equally performed to form doped regions having different depths. In the semiconductor device 202, since the thickness D2p of the peripheral region substrate 211 is greater than the thickness D2c of the cell region substrate 210, when implanting is performed at the same level, the depth of the doped region from the first surface 210a of the cell region substrate 210 may be smaller than the depth of the doped region from the first surface 211a of the peripheral region substrate 211.

Referring to FIG. 10C, the semiconductor device 203 according to an embodiment may include the semiconductor device 200P illustrated in FIG. 9A. For example, the memory cell region substrate 210 of the semiconductor device 203 may include the cell active region AC defined by the cell device isolation layer 215, and the first surface 215a of the cell device isolation layer 215 may be positioned to be coplanar with the first surface 210a of the cell region substrate 210, but the second surface 215b of the cell device isolation layer 215 may not be positioned to be coplanar with the second surface 210b of the cell region substrate 210. For example, the peripheral region substrate 211 of the semiconductor device 203 may include the peripheral active region AC defined by the peripheral device isolation layer 212, the first surface 212a of the peripheral device isolation layer 212 may be positioned to be coplanar with the first surface 211a of the peripheral region substrate 211, and the second surface 212b of the peripheral device isolation layer 212 may be positioned to be coplanar with the second surface 211b of the peripheral region substrate 211. For example, the second surface 215b of the cell device isolation layer 215 of the semiconductor device 203 may be disposed in the cell region substrate 210 and may be positioned at a vertical level higher than the second surface 201b of the cell region substrate 210.

In some embodiments, a thickness of the cell region substrate 210 of the semiconductor device 203 in the vertical direction D4 may be D3c, and a thickness of the peripheral region substrate 211 in the vertical direction D4 may be D3p. By performing grinding of the cell region substrate 210 and the peripheral region substrate 211 at different levels, the thickness D3c of the cell region substrate 210 may be greater than the thickness D3p of the peripheral region substrate 211.

In some embodiments, in the semiconductor device 203 in which the thickness D3c of the cell region substrate 210 is different from the thickness D3p of the peripheral region substrate 211, implanting in the second surface 210b of the cell region substrate 210 and implanting in the second surface 211b of the peripheral region substrate 211 may be equally perform to form doped regions having different depths. In the semiconductor device 203, since the thickness D3p of the peripheral region substrate 211 is less than the thickness D3c of the cell region substrate 210, when implanting is performed at the same level, the depth of the doped region from the first surface 210a of the cell region substrate 210 may be deeper than the depth of the doped region from the first surface 211a of the peripheral region substrate 211.

In some other embodiments of FIGS. 10A to 10C, implanting may be performed only on the second surface 210b of the cell region substrate 210, or implanting may be performed only on the second surface 211b of the peripheral region substrate 211.

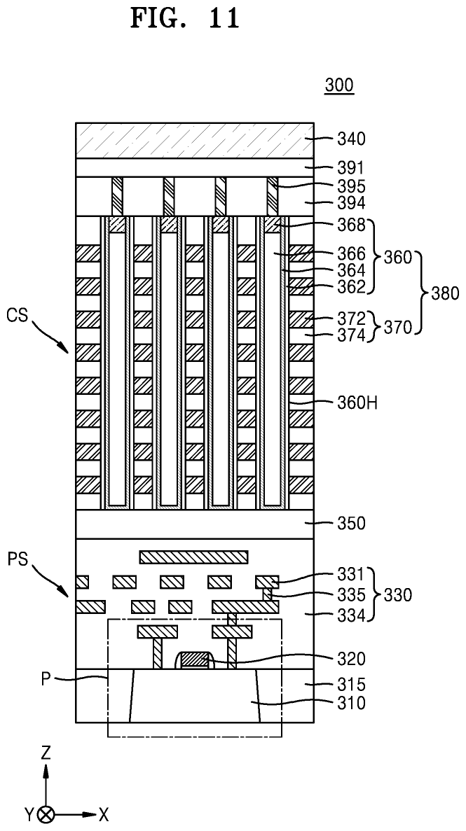

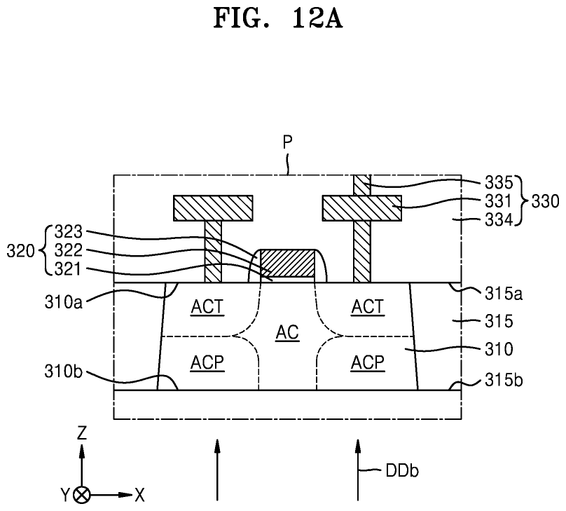

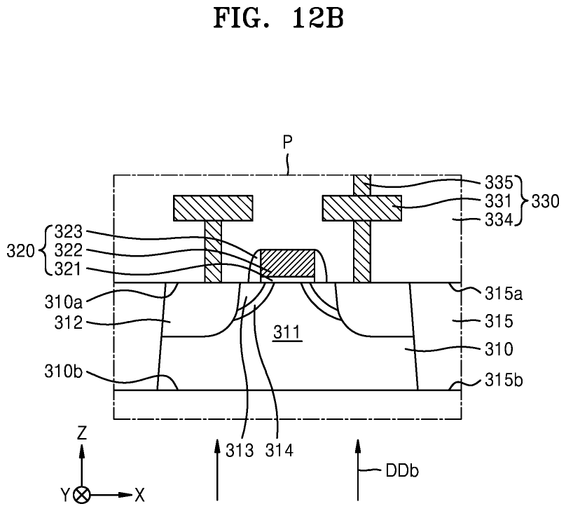

FIG. 11 is a cross-sectional view illustrating a semiconductor device 300 according to an embodiment. FIGS. 12A and 12B are enlarged cross-sectional views of region P of FIG. 11 schematically illustrating some components of the semiconductor device 300 according to embodiments of the present inventive concept.

Referring to FIGS. 11 and 12A together, the semiconductor device 300 according to embodiments of the present inventive concept may include a peripheral structure PS, a cell structure CS disposed on the peripheral structure PS, and a protective layer 340 covering the cell structure CS and including an insulating material.

In an embodiment shown in FIG. 11, the semiconductor device 300 may have a cell on periphery (COP) structure in which the cell structure CS is disposed on the peripheral structure PS (e.g., in the vertical direction Z). A base structure 350 may be disposed between the peripheral structure PS and the cell structure CS (e.g., in the vertical direction Z).

The peripheral structure PS may include a substrate 310 including a first surface 310a and a second surface 310b opposing each other (e.g., in the vertical direction Z), a device isolation layer 315 extending through the substrate 310 and defining the active region AC in the substrate 310, a gate electrode 322 on the first surface 310a of the substrate 310, and a wiring structure 330 electrically connected to the gate electrode 322 on the first surface 310a, of the substrate 310 and the active region AC.

In some embodiments, a description of the components of the peripheral structure PS of the semiconductor device 300 may be similar to the description of the components of the semiconductor device 100 with reference to FIGS. 1 to 4 and a repeated description may be omitted for economy of description.

For example, the device isolation layer 315 defining the active regions AC may be formed in the substrate 310 of the semiconductor device 300. A first surface 315a of the device isolation layer 315 may be positioned to be coplanar with the first surface 310a of the substrate 310, and a second surface 315b of the device isolation layer 315 may be positioned to be coplanar with the second surface 310b of the substrate 310. In an embodiment, a width of the first surface 315a of the device isolation layer 315 in the first horizontal direction (the X direction) may be greater than a width of the second surface 315b of the device isolation layer 315 in the first horizontal direction (the X direction).

In some embodiments, the active region AC may include the target doped region ACT positioned between the device isolation layer 315 and the gate electrode 322 and including a dopant having a first concentration and the path doped region ACP positioned between the device isolation layer 315 and the gate electrode 322, including a dopant having a second concentration smaller than the first concentration, and extending from the second surface 310b of the substrate 310 to the target doped region ACT. In some embodiments, the target doped region ACT and the path doped region ACP may include the same type of dopant, but the first concentration of the dopant included in the target doped region ACT may be higher than the second concentration of the dopant included in the path doped region ACP. In some embodiments, the target doped region ACT may include a higher concentration of dopant than the path doped region ACP due to a doping process of the target doped region ACT being performed through the second surface 310b of the substrate 310 in the second doping direction DDb.

In some embodiments, a transistor 320 may be disposed on the first surface 310a of the substrate 310. The transistor 320 may include a gate insulating layer 321, a gate electrode 322, and a spacer 323. The spacer 323 may define a gate trench, and the gate insulating layer 321 and the gate electrode 322 may be sequentially disposed in the gate trench (e.g., in the vertical direction Z).

In some embodiments, the wiring structure 330 may include an interlayer insulating layer 334 and a plurality of wiring pads 331 and a plurality of wiring contacts 335 disposed in the interlayer insulating layer 334.

The cell structure CS may include a stack structure 370 including a plurality of conductive layers 372 disposed on the wiring structure 330 of the peripheral structure PS and including a plurality of interlayer insulating layers 374 and a channel structure 360 passing through the stack structure 370.

In an embodiment, the stack structure 370 may extend in the first horizontal direction (the X direction) and the second horizontal direction (a Y direction) parallel to the first surface 310a of the substrate 310 on the substrate 310. The stack structure 370 may include the conductive layers 372 and the interlayer insulating layers 374, and the conductive layers 372 and the interlayer insulating layers 374 may be disposed in the vertical direction (e.g., the Z direction) perpendicular to the upper surface of the substrate 310. An upper insulating layer 394 may be disposed on the uppermost portion of the stack structure 370.

In an embodiment, the conductive layer 372 may include a buried conductive layer and an insulating liner surrounding the top, bottom, and lateral side surfaces of the buried conductive layer. For example, in an embodiment the buried conductive layer may include a metal, such as tungsten, a metal silicide, such as tungsten silicide, doped polysilicon, or combinations thereof. In some embodiments, the insulating liner may include a high dielectric material, such as aluminum oxide.

The channel structure 360 may extend in the vertical direction (e.g., the Z direction) through the conductive layer 372 from the upper surface of the substrate 310 in the cell structure CS. The channel structures 360 may be arranged to be spaced apart from each other at certain intervals in the first horizontal direction (the X direction) and the second horizontal direction (the Y direction). In an embodiment, the channel structures 360 may be arranged in a zigzag shape or a staggered shape.

The channel structure 360 may be formed to extend inside the channel hole 360H passing through the stack structure 370. Each of the channel structures 360 may include a gate insulating layer 362, a channel layer 364, a buried insulating layer 366, and a conductive plug 368. The gate insulating layer 362 and the channel layer 364 may be sequentially disposed on a sidewall of the channel hole 360H. For example, the gate insulating layer 362 may be conformally disposed on the sidewall of the channel hole 360H, and the channel layer 364 may be conformally disposed on the sidewall and a bottom portion of the channel hole 360H. The buried insulating layer 366 filling a remaining space of the channel hole 360H may be disposed on the channel layer 364. The conductive plug 368 may be disposed on an upper side of the channel hole 360H to contact the channel layer 364 and block an entrance (e.g., the uppermost end) of the channel hole 360H. However, embodiments of the present inventive concept are not necessarily limited thereto. For example, in some embodiments, the buried insulating layer 366 may be omitted, and the channel layer 364 may be formed in a pillar shape to fill the remaining portion of the channel hole 360H. A region occupied by the channel layer 364 and the buried insulating layer 366 may have a rectangular shape having a horizontal width substantially constant in the vertical direction (e.g., the Z direction) from an upper region to a lower region thereof.

The channel structure 360 may contact the substrate 310. In some embodiments, the channel layer 364 may be disposed to contact the upper surface of the substrate 310 at the bottom portion of the channel hole 360H. In some embodiments, a contact semiconductor layer having a certain height may be formed on the substrate 310 at the bottom portion of the channel hole 360H, and the channel layer 364 may be electrically connected to the substrate 310 through the contact semiconductor layer.

The gate insulating layer 362 may have a triple-layer structure including a tunneling dielectric layer, a charge storage layer and a blocking dielectric layer sequentially formed on an outer wall of the channel layer 364.

In an embodiment, the tunneling dielectric layer may include silicon oxide, hafnium oxide, aluminum oxide, zirconium oxide, tantalum oxide, or the like. The charge storage layer is a region in which electrons passing through the tunneling dielectric layer from the channel layer 364 may be stored, and may include silicon nitride, boron nitride, silicon boron nitride, or polysilicon doped with impurities. The blocking dielectric layer may include silicon oxide, silicon nitride, or metal oxide having higher permittivity than that of silicon oxide. However, embodiments of the present inventive concept are not necessarily limited thereto.

The bit line contact 395 may pass through the upper insulating layer 394 to contact the conductive plug 368 of the channel structure 360, and a bit line 391 contacting the bit line contact 395 may extend on the upper insulating layer in the first horizontal direction (e.g., the X direction).

In some embodiments, the protective layer 340 may be disposed on the cell structure CS. For example, the protective layer 340 may be disposed on the stack structure 370. For example, the protective layer 340 may be disposed to cover an upper surface of the stack structure 370. The protective layer 340 may be disposed on the components of the semiconductor device 300, such as the gate electrode 322, the wiring structure 330, and the stack structure 370, to cover the components. The protective layer 340 may be formed to protect the components disposed on the first surface 310a of the substrate 310 in a subsequent process. For example, the protective layer 340 may protect the components of the semiconductor device 300 from physical impact. In some embodiments, the protective layer 340 may include an insulating material. In some embodiments, the protective layer 340 may protect the components of the semiconductor device 300 from unwanted electrical signals.

In some embodiments, the protective layer 340 may include portions surrounding upper and side surfaces of the stack structure 370. Accordingly, the protective layer 340 may protect the side surface as well as the upper surface of the stack structure 370.

Referring to FIG. 12B, the active region AC (refer to FIG. 12A) may include a first region 311, a second region 312. a third region 313, and a fourth region 314. The first region 311 may include a doped region in the active region AC defined by the device isolation layer 315, and may refer to a portion excluding the second region 312 to the fourth region 314 in the active region AC. The second region 312 may be positioned between the device isolation layer 315 and the gate electrode 322, and may abut the first surface 310a of the substrate 310. The third region 313 may be positioned between the second region 312 and the gate electrode 322, and may abut the first surface 310a of the substrate 310. The fourth region 314 may be positioned between the first region 311 and the third region 313 and surround the third region 313, such as surround a lower surface of the third region 313. The fourth region 314 may abut the first surface 310a of the substrate 310.

In some embodiments, the second region 312 and the third region 313 may be doped with a dopant having the same conductivity type. In some embodiments, the first region 311 and the fourth region 314 may be doped with a dopant having the same conductivity type. In some embodiments, the first region 311 and the second region 312 may be doped with dopants having different conductivity types.

In some embodiments, the second region 312 and the third region 313 doped with a dopant having the same conductivity type may be doped to have different concentrations. For example, a third doping concentration of the third region 313 may be less than a second doping concentration of the second region 312. In some embodiments, the first region 311 and the fourth region 314 doped with a dopant having the same conductivity type may be doped with different concentrations. For example, a fourth doping concentration of the fourth region 314 may be higher than a first doping concentration of the first region 311. Alternatively, for example, the fourth doping concentration of the fourth region 314 may be less than the first doping concentration of the first region 311. However, the first doping concentration to the fourth doping concentration of the first region 311 to the fourth region 314 may be variously selected and embodiments of the present inventive concept are not necessarily limited to those described above. In some embodiments, the first doping concentration to the fourth doping concentration of the first region 311 to the fourth region 314 of the semiconductor device 300 may be different from the first doping concentration to the fourth doping concentration of the first region 111 to the fourth region 114 of the semiconductor device 100.

In some embodiments, doping of the first region 311 to the fourth region 314 illustrated in FIG. 12B may be performed in the second doping direction DDb through the second surface 310b of the substrate 310. For example, a dopant may be implanted into the first region 311 through the second surface 310b of the substrate 310. In a subsequent doping of the second region 312 to the fourth region 314, a dopant may be implemented in the second doping direction DDb through the second surface 310b of the substrate 310. That is, a dopant source implanted in the first region 311 to the fourth region 314 may be located outside the second surface 310b of the substrate 310.

In some embodiments, the semiconductor device may include an LDD halo well structure. The first region 311 may include a well region. The third region 313 may include an LDD region. The second region 312 and the third region 313 may include source/drain regions of the transistor 120. The fourth region 314 may include a halo region. In some embodiments, an LDD halo well structure of the semiconductor device 300 may be a structure formed by implanting a dopant in the second doping direction DDb through the second surface 310b of the substrate 310. For example, a well region of the first region 311, an LDD region of the third region 313, and a halo region of the fourth region 314 may be a structure formed by a doping process through the second surface 310b of the substrate 310 in the second doping direction DDb.

While the inventive concept has been particularly shown and described with reference to embodiments thereof, it will be understood that various changes in form and details may be made therein without departing from the spirit and scope of the present inventive concept.

What is claimed is:

1. A semiconductor device comprising:
a substrate including first and second surfaces opposing each other;
a device isolation layer extending through the substrate, the device isolation layer defining an active region in the substrate;
a gate electrode on the first surface of the substrate;
a wiring structure on the first surface of the substrate, the wiring structure is electrically connected to the gate electrode and the active region; and
a protective layer covering the wiring structure, the protective layer including an insulating material,
wherein a first surface of the device isolation layer is coplanar with the first surface of the substrate, and
a second surface of the device isolation layer is coplanar with the second surface of the substrate,
wherein the active region includes:
a target doped region between the device isolation layer and the gate electrode, the target doped region including a dopant having a first concentration; and
a path doped region between the device isolation layer and the gate electrode and extending from the second surface of the substrate to the target doped region, the path doped region including a dopant having a second concentration less than the first concentration,
wherein the target doped region abuts the first surface of the substrate,
the path doped region abuts the second surface of the substrate,
the target doped region and the path doped region are formed by implanting the dopant through the second surface of the substrate, and
the substrate is thinned by grinding the second surface of the substrate to expose the second surface of the device isolation layer.

2. The semiconductor device of claim 1, wherein:
the wiring structure includes an interlayer insulating layer, a plurality of wiring pads disposed in the interlayer insulating layer and a plurality of wiring contacts disposed in the interlayer insulating layer,
wherein the semiconductor device further comprises an active contact disposed on the first surface of the substrate, the active contact electrically connecting the wiring structure to the active region.

3. The semiconductor device of claim 1, wherein a width of the first surface of the device isolation layer in a horizontal direction is greater than a width of the second surface of the device isolation layer in the horizontal direction.

4. The semiconductor device of claim 1, wherein the semiconductor device comprises a dynamic random-access memory (DRAM) or a NAND FLASH memory device.

5. The semiconductor device of claim 1, wherein:
the active region includes:
a first region including a well region;
a second region abuts the first surface of the substrate and is disposed between the device isolation layer and the gate electrode;
a third region is between the second region and the gate electrode; and
a fourth region surrounds the third region and is disposed between the first region and the third region,
wherein the second region and the third region are doped with a dopant having a same conductivity type,
the first region and the fourth region are doped with a dopant having the same conductivity type,
the first region and the second region are doped with dopants having different conductivity types from each other, and
a third doping concentration of the third region is lower than a second doping concentration of the second region.

6. The semiconductor device of claim 5, wherein:
the third region includes a lightly doped drain (LDD) region; and
the fourth region includes an LL)D halo well structure including a halo region.

7. The semiconductor device of claim 5, wherein the dopants of the first to fourth regions are implanted through the second surface of the substrate.

8. A semiconductor device comprising:
a substrate including first and second surfaces opposite to each other;
a device isolation layer extending through the substrate in a vertical direction, the device isolation layer defining an active region in the substrate;
a gate electrode structure disposed within the substrate, the gate electrode structure extending in a first horizontal direction;
a wiring structure on the substrate; and
a protective layer covering the wiring structure, the protective layer including an insulating material,
wherein the wiring structure includes a bit line ; the bit line extending in a second horizontal direction orthogonal to the first horizontal direction,
a first surface of the device isolation layer is coplanar with the first surface of the substrate, and
a second surface of the device isolation layer is coplanar with the second surface of the substrate,
wherein the active region includes:
a target doped region between the device isolation layer and the gate electrode structure, the target doped region including a dopant having a first concentration; and
a path doped region between the device isolation layer and the gate electrode structure, the path doped region extending from the second surface of the substrate to the target doped region, the path doped region including a dopant having a second concentration less than the first concentration,
wherein the target doped region abuts the first surface of the substrate,
the path doped region abuts the second surface of the substrate,
the target doped region and the path doped region are formed by implanting the dopant through the second surface of the substrate, and
the substrate is thinned by grinding the second surface of the substrate to expose the second surface of the device isolation layer.

9. The semiconductor device of claim 8 ; wherein the wiring structure includes an interlayer insulating layer and a contact structure disposed in the interlayer insulating layer.

10. The semiconductor device of claim 8, wherein a width of the first surface of the device isolation layer in the first horizontal direction is greater than a width of the second surface of the device isolation layer in the first horizontal direction.

11. The semiconductor device of claim 8, wherein the protective layer includes a portion surrounding an upper surface and a lateral side surface of the wiring structure.

12. The semiconductor device of claim 8, wherein:
the substrate includes a cell region;
the active region includes a cell active region;
the device isolation layer includes a cell device isolation layer disposed in the cell region;
the cell device isolation layer defining the cell active region;
the gate electrode structure includes a cell gate electrode disposed in the cell region;
the wiring structure includes a cell wiring structure disposed in the cell region and further includes a cell capacitor structure disposed on the cell wiring structure, the cell capacitor structure is electrically connected to the cell active region in the substrate; and
the protective layer is disposed on the cell capacitor structure.

13. The semiconductor device of claim 8, wherein:
the substrate includes a peripheral region;
the active region includes a peripheral active region;
the device isolation layer includes a peripheral device isolation layer disposed in the peripheral region, the peripheral device isolation layer defining the peripheral active region;
the gate electrode structure includes a peripheral gate electrode disposed in the peripheral region;
the wiring structure includes a peripheral wiring structure disposed in the peripheral region; and
the protective layer is disposed on the peripheral wiring structure.

14. The semiconductor device of claim 13, wherein:
the peripheral active region includes a first region including a well region;
a second region is adjacent to the first surface of the substrate and is disposed between the peripheral device isolation layer and the peripheral gate electrode;
a third region is between the second region and the peripheral gate electrode; and
a fourth region surrounds the third region and is disposed between the first region and the third region, and
wherein the second region and the third region are doped with a dopant having a same conductivity type,
the first region and the fourth region are doped with a dopant having the same conductivity type,
the first region and the second region are doped with dopants having different conductivity types from each other, and
a third doping concentration of the third region is lower than a second doping concentration of the second region.

15. A semiconductor device comprising:
a peripheral structure;
a cell structure on the peripheral structure; and
a protective layer covering the cell structure, the protective layer including an insulating material,
wherein the peripheral structure includes:
a substrate including first and second surfaces opposing each other;
a device isolation layer extending through the substrate, the device isolation layer defining an active region in the substrate;
a gate electrode on the first surface of the substrate; and
a wiring structure on the first surface of the substrate, the wiring structure is electrically connected to the gate electrode,
wherein the cell structure includes:
a stack structure disposed on the wiring structure and including a plurality of conductive layers and a plurality of interlayer insulating layers that are alternately stacked; and
a channel structure extending through the stack structure,
wherein a first surface of the device isolation layer is coplanar with the first surface of the substrate, and
a second surface of the device isolation layer is coplanar with the second surface of the substrate,
wherein the active region includes:
a target doped region between the device isolation layer and the gate electrode, the target doped region including a dopant having a first concentration; and
a path doped region between the device isolation layer and the gate electrode and extending from the second surface of the substrate to the target doped region, the path doped region including a dopant having a second concentration less than the first concentration,
wherein the target doped region abuts the first surface of the substrate,
the path doped region abuts the second surface of the substrate,
the target doped region and the path doped region are formed by implanting the dopant through the second surface of the substrate, and
the substrate is thinned by grinding the second surface of the substrate to expose the second surface of the device isolation layer.

16. The semiconductor device of claim 15, wherein a width of the first surface of the device isolation layer in a horizontal direction is greater than a width of the second surface of the device isolation layer in the horizontal direction.

17. The semiconductor device of claim 15, wherein the wiring structure includes an interlayer insulating layer, a plurality of wiring pads disposed in the interlayer insulating layer and a plurality of wiring contacts disposed in the interlayer insulating layer.

18. The semiconductor device of claim 15, wherein the protective layer includes a portion surrounding an upper surface and a lateral side surface of the wiring structure.

19. The semiconductor device of claim 15, wherein:
the active region includes a first region including a well region;
a second region is adjacent to the first surface and disposed between the device isolation layer and the gate electrode;
a third region is between the second region and the gate electrode; and
a fourth region surrounds the third region between the first region and the third region,
wherein the second region and the third region are doped with a dopant having a same conductivity type,
the first region and the fourth region are doped with a dopant having the same conductivity type,
the first region and the second region are doped with dopants having different conductivity types from each other, and
a third doping concentration of the third region is lower than a second doping concentration of the second region.

20. The semiconductor device of claim 19, wherein:
the third region includes a lightly doped drain (LDD) region; and
the fourth region includes an LDD halo well structure including a halo region.
